(19) United States
(12) Patent Application Publication
(10) Pub. No.: US 2025/0030400 A1
(43) Pub. Date: Jan. 23, 2025

(54) ACOUSTIC WAVE DEVICE

(71) Applicant: Murata Manufacturing Co., Ltd., Nagaokakyo-shi (JP)

(72) Inventors: Takuya YABU, Nagaokakyo-shi (JP); Kentaro NAKAMURA, Nagaokakyo-shi (JP)

(21) Appl. No.: 18/736,827

(22) Filed: Jun. 7, 2024

(30) Foreign Application Priority Data
Jul. 20, 2023 (JP) 2023-118304

(51) Int. Cl. H03H 9/145; H03H 9/02; H03H 9/25; H03H 9/64

(52) U.S. Cl. CPC H03H 9/14561; H03H 9/02692; H03H 9/02866; H03H 9/02889; H03H 9/25; H03H 9/6483

(57) ABSTRACT

An acoustic wave device includes acoustic wave resonators each including a piezoelectric substrate including a piezoelectric body layer, and an IDT electrode on the piezoelectric substrate and including electrode fingers. At least one of the acoustic wave resonators is an excitation angle change resonator, in which, the piezoelectric body layer includes a propagation axis and the electrode fingers are curved. In the excitation angle change resonator, an excitation direction of an acoustic wave in a portion of one of the electrode fingers is one of first, second, or third directions. An excitation angle of the excitation angle change resonator is not uniform in the IDT electrode.

### CROSS REFERENCE TO RELATED APPLICATIONS

This application claims the benefit of priority to Japanese Patent Application No. 2023-118304 filed on Jul. 20, 2023. The entire contents of this application are hereby incorporated herein by reference.

### BACKGROUND OF THE INVENTION

### 1. Field of the Invention

The present invention relates to acoustic wave devices including a plurality of acoustic wave resonators.

### 2. Description of the Related Art

In the related art, acoustic wave devices are widely used for, for example, filters of mobile phones. International Publication No. 2018/003297 discloses an example of a multiplexer in which a plurality of acoustic wave resonators are used as a series resonator or a parallel resonator. The multiplexer includes two duplexers. Each of the two duplexers includes two filters. Each filter is connected in common to a common terminal.

One filter includes a plurality of series resonators and a plurality of parallel resonators. In the filter, the series resonator closest to the common terminal side is formed by a plurality of divided resonators divided in series. All of the divided resonators include an interdigital transducer (IDT) electrode and a reflector. The plurality of divided resonators are different in at least one of an electrode finger pitch, an intersection width, the number of pairs of electrode fingers, a duty, and a distance between the IDT electrode and the reflector.

In the multiplexer described in International Publication No. 2018/003297, the series resonators need to be divided in series more to sufficiently suppress unwanted waves. Therefore, a total area of the divided resonators tends to increase. On the other hand, when the number of the divided resonators is small, it is difficult to sufficiently suppress the unwanted waves.

### SUMMARY OF THE INVENTION

Example embodiments of the present invention provide acoustic wave devices which are each able to reduce or prevent unwanted waves.

According to an example embodiment of the present invention, an acoustic wave device includes a plurality of acoustic wave resonators each including a piezoelectric substrate including a piezoelectric body layer, and an IDT electrode on the piezoelectric substrate and including a plurality of electrode fingers. At least one of the plurality of acoustic wave resonators is an excitation angle change resonator. In the excitation angle change resonator, the piezoelectric body layer includes a propagation axis, and the plurality of electrode fingers are curved. In the excitation angle change resonator, an excitation direction of an acoustic wave in a portion of an electrode finger in the plurality of electrode fingers is one of a first direction perpendicular or substantially perpendicular to an extending direction of the electrode finger, a second direction connecting a shortest distance between the electrode finger and an electrode finger adjacent to the electrode finger, and a third direction of an electric field vector generated between the electrode finger and the electrode finger adjacent to the electrode finger. In the excitation angle change resonator, when an angle between the excitation direction and an extending direction of the propagation axis is defined as an excitation angle, the excitation angle is not uniform in the IDT electrode. The plurality of acoustic wave resonators are connected to each other in series or in parallel. Other elements are not connected between the plurality of acoustic wave resonators. A circuit of the filter device is not branched between the plurality of acoustic wave resonators.

According to example embodiments of the present invention, unwanted waves are able to be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a filter device according to an example embodiment of the present invention.

FIG. 3 is a schematic plan view of a first acoustic wave resonator in the first example embodiment of the present invention.

FIG. 4 is a schematic cross-sectional view taken along a two-dot chain line N in FIG. 3.

FIG. 5 is a schematic plan view of a second acoustic wave resonator in the first example embodiment of the present invention.

FIG. 6 is a schematic plan view of an acoustic wave device of a comparative example.

FIG. 7 is a view showing phase characteristics in the vicinity of a frequency at which unwanted waves are generated in the first example embodiment and the comparative example of the present invention.

FIG. 8 is a schematic plan view of an acoustic wave device according to a first modified example of the first example embodiment of the present invention.

FIG. 9 is a schematic plan view of a first acoustic wave resonator in the first modified example of the first example embodiment of the present invention.

FIG. 10 is a schematic plan view showing a circle including an arc when a shape of an electrode finger in a plan view of a first IDT electrode in the first modified example of the first example embodiment of the present invention is approximated to the arc.

FIG. 11 is a schematic plan view of an acoustic wave device according to a second modified example of the first example embodiment of the present invention.

FIG. 12 is a schematic plan view of a first acoustic wave resonator in the second modified example of the first example embodiment of the present invention.

FIG. 13 is a schematic plan view showing a parallel region and a non-parallel region in the second modified example of the first example embodiment of the present invention.

FIG. 14 is a schematic plan view of a first acoustic wave resonator in a third modified example of the first example embodiment of the present invention.

FIG. 15 is a schematic plan view of a first acoustic wave resonator in a fourth modified example of the first example embodiment of the present invention.

FIG. 16 is a schematic plan view of a first acoustic wave resonator in a fifth modified example of the first example embodiment of the present invention.

FIG. 17 is a schematic plan view showing the vicinity of a first edge region and a second edge region in a sixth modified example of the first example embodiment of the present invention.

FIG. 18A is a schematic cross-sectional view showing a cross section along an extending direction of a first electrode finger in the vicinity of a first edge region, a second edge region, and a central region of a first electrode finger in a seventh modified example of the first example embodiment of the present invention; FIG. 18B is a schematic cross-sectional view showing a cross section along an extending direction of a second electrode finger in the vicinity of the first edge region, the second edge region, and the central region of a second electrode finger in the seventh modified example of the first example embodiment of the present invention.

FIG. 19 is a schematic plan view of a first acoustic wave resonator in an eighth modified example of the first example embodiment of the present invention.

FIG. 20 is a schematic plan view of an acoustic wave device according to a ninth modified example of the first example embodiment of the present invention.

FIG. 21 is a schematic plan view of an acoustic wave device according to a second example embodiment of the present invention.

FIG. 22 is a schematic plan view of an acoustic wave device according to a third example embodiment of the present invention.

FIG. 23 is a view showing phase characteristics in the vicinity of the frequency where the unwanted waves are generated in the first example embodiment, the third example embodiment, and a comparative example of the present invention.

FIG. 24 is a schematic plan view of an acoustic wave device according to a first modified example of the third example embodiment of the present invention.

FIG. 25 is a schematic plan view of an acoustic wave device according to a second modified example of the third example embodiment of the present invention.

FIG. 26 is a view showing phase characteristics in the vicinity of the frequency where the unwanted waves are generated in the first example embodiment, the second modified example and a comparative example of the third example embodiment of the present invention.

FIG. 27 is a schematic plan view of an acoustic wave device according to a third modified example of the third example embodiment of the present invention.

FIG. 28 is a schematic plan view of an acoustic wave device according to a fourth example embodiment of the present invention.

FIG. 29 is a schematic plan view of an acoustic wave device according to a modified example of the fourth example embodiment of the present invention.

FIG. 30 is a schematic plan view of an acoustic wave device according to a fifth example embodiment of the present invention.

FIG. 31 is a view showing phase characteristics in the vicinity of the frequency where the unwanted waves are generated in the first example embodiment, the fifth example embodiment, and a comparative example of the present invention.

FIG. 32 is a schematic plan view of an acoustic wave device according to a modified example of the fifth example embodiment of the present invention.

FIG. 33 is a schematic elevational cross-sectional view of an acoustic wave device according to a sixth example embodiment of the present invention.

FIG. 34 is a schematic elevational cross-sectional view of an acoustic wave device according to a first modified example of the sixth example embodiment of the present invention.

FIG. 35 is a schematic elevational cross-sectional view of an acoustic wave device according to a second modified example of the sixth example embodiment of the present invention.

FIG. 36 is a schematic elevational cross-sectional view of an acoustic wave device according to a seventh example embodiment of the present invention.

FIG. 37 is a schematic elevational cross-sectional view of an acoustic wave device according to an eighth example embodiment of the present invention.

FIG. 38 is a schematic elevational cross-sectional view of an acoustic wave device according to a first modified example of the eighth example embodiment of the present invention.

FIG. 39 is a schematic elevational cross-sectional view of an acoustic wave device according to a second modified example of the eighth example embodiment of the present invention.

FIG. 40 is a schematic elevational cross-sectional view of an acoustic wave device according to a third modified example of the eighth example embodiment of the present invention.

### DETAILED DESCRIPTION OF THE EXAMPLE EMBODIMENTS

Hereinafter, the present invention will be clearly understood by describing example embodiments of the present invention with reference to the drawings.

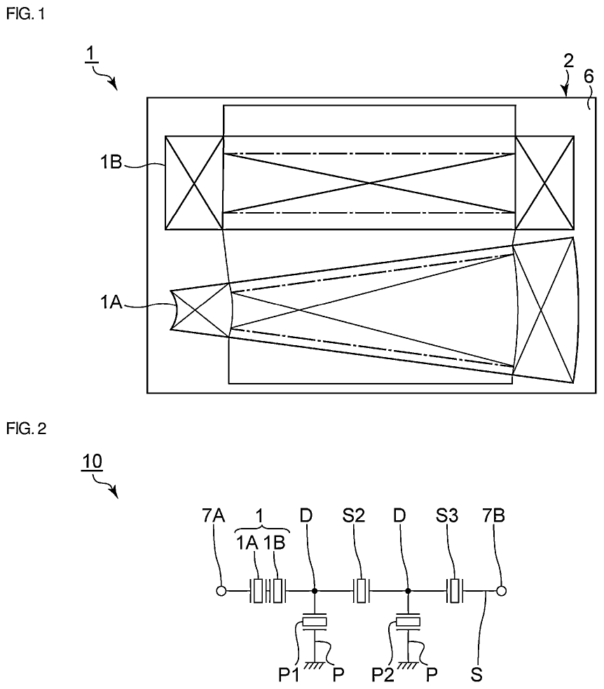

Each example embodiment described in the present specification is merely an example, and configurations can be partially replaced or combined with each other between different example embodiments. FIG. 1 is a schematic plan view of an acoustic wave device according to a first example embodiment of the present invention. In FIG. 1, an IDT electrode and a reflector (to be described later) are shown by a schematic view in which two diagonal lines are added to a figure including a curve or a rectangle.

An acoustic wave device 1 shown in FIG. 1 is used as a portion of a filter device. The acoustic wave device 1 includes a plurality of acoustic wave resonators. In the present example embodiment, the plurality of acoustic wave resonators include a first acoustic wave resonator 1A and a second acoustic wave resonator 1B.

FIG. 2 shows a filter device according to an example embodiment of the present invention.

A filter device 10 is, for example, a ladder filter. The filter device 10 includes a plurality of series arm resonators and a plurality of parallel arm resonators. The first acoustic wave resonator 1A and the second acoustic wave resonator 1B in the first example embodiment are divided resonators divided in series. That is, the first acoustic wave resonator 1A and the second acoustic wave resonator 1B are connected to each other in series, and other elements are not connected between the first acoustic wave resonator 1A and the second acoustic wave resonator 1B. A circuit of the filter device 10 is not branched between the first acoustic wave resonator 1A and the second acoustic wave resonator 1B.

For example, the first acoustic wave resonator 1A and the second acoustic wave resonator 1B may be divided resonators divided in parallel. In the filter device 10, the first acoustic wave resonator 1A and the second acoustic wave resonator 1B are series arm resonators. However, the first acoustic wave resonator 1A and the second acoustic wave resonator 1B may be parallel arm resonators divided in series or divided in parallel.

The plurality of acoustic wave resonators of the acoustic wave device according to example embodiments of the present invention may be resonators corresponding to the divided resonators, as a circuit configuration. For example, resonant frequencies of the plurality of acoustic wave resonators do not need to coincide with each other.

As will be described in detail later, the first acoustic wave resonator 1A in the acoustic wave device 1 is an excitation angle change resonator. On the other hand, the second acoustic wave resonator 1B is an acoustic wave resonator that is not an excitation angle change resonator. The acoustic wave device may include at least two acoustic wave resonators. The plurality of acoustic wave resonators may include at least one excitation angle change resonator. Hereinafter, a specific configuration of the acoustic wave device 1 in the first example embodiment will be described.

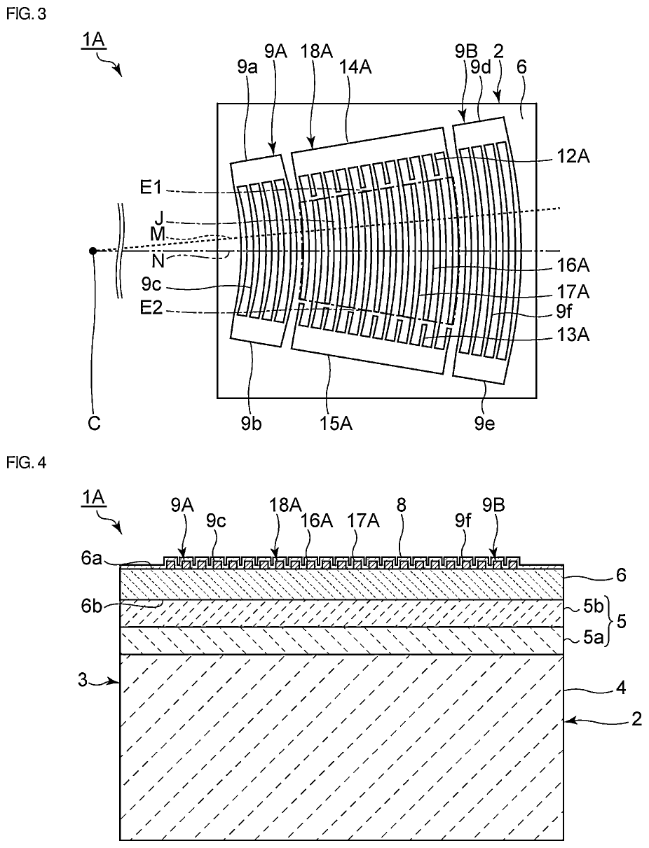

FIG. 3 is a schematic plan view of a first acoustic wave resonator in the first example embodiment. FIG. 4 is a schematic cross-sectional view taken along a two-dot chain line N in FIG. 3.

As shown in FIGS. 3 and 4, the first acoustic wave resonator 1A includes a piezoelectric substrate 2. As shown in FIG. 4, the piezoelectric substrate 2 is a multilayer substrate including a piezoelectric body layer 6. That is, the piezoelectric substrate 2 is a substrate having piezoelectricity. Specifically, the piezoelectric substrate 2 includes a support member 3 and the piezoelectric body layer 6. More specifically, the support member 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric body layer 6 is provided on the second layer 5b. A layer configuration of the piezoelectric substrate 2 is not limited to the above-described example. For example, the intermediate layer 5 may be a single dielectric layer. Alternatively, the piezoelectric substrate 2 may be a substrate including only the piezoelectric body layer 6.

In the first example embodiment, for example, silicon is used as a material of the support substrate 4. Silicon nitride is used as a material of the first layer 5a, for example. Silicon oxide is used as a material of the second layer 5b, for example. Rotational Y-cut X-propagation lithium tantalate is used as a material of the piezoelectric body layer 6. In this way, the piezoelectric body layer 6 has a propagation axis. A direction of the propagation axis is an X-direction. However, the material of each layer of the piezoelectric substrate 2 is not limited to the above-described example.

The piezoelectric body layer 6 includes a first main surface 6a and a second main surface 6b. The first main surface 6a and the second main surface 6b face each other. The second main surface 6b in the first main surface 6a and the second main surface 6b is located on the support substrate 4 side. A first IDT electrode 18A is provided on the first main surface 6a of the piezoelectric body layer 6. In this manner, the first acoustic wave resonator 1A is provided.

As shown in FIG. 3, the first IDT electrode 18A includes a pair of busbars and a plurality of electrode fingers. Specifically, the pair of busbars include a first busbar 14A and a second busbar 15A. The first busbar 14A and the second busbar 15A face each other. Specifically, the plurality of electrode fingers are a plurality of first electrode fingers 16A and a plurality of second electrode fingers 17A. One end of each of the plurality of first electrode fingers 16A is connected to the first busbar 14A. One end of each of the plurality of second electrode fingers 17A is connected to the second busbar 15A.

Each of the plurality of first electrode fingers 16A and the plurality of second electrode fingers 17A includes a base end portion, a tip portion, and a pair of end edge portions. Specifically, the base end portion of the first electrode finger 16A is connected to the first busbar 14A. The pair of end edge portions of the first electrode finger 16A connect the base end portion and the tip portion. The base end portion of the second electrode finger 17A is connected to the second busbar 15A. The pair of end edge portions of the second electrode finger 17A connect the base end portion and the tip portion in a plan view. The plurality of first electrode fingers 16A and the plurality of second electrode fingers 17A are interdigitated with each other. In the present specification, a plan view means a view when viewed a direction corresponding to an upper side in FIG. 4. In FIG. 4, for example, the piezoelectric body layer 6 side on the support substrate 4 side and the piezoelectric body layer 6 side is the upper side.

Each tip portion of the plurality of first electrode fingers 16A and the plurality of second electrode fingers 17A includes a tip. A virtual line connecting the tips of the plurality of second electrode fingers 17A is defined as a first envelope curve E1. Similarly, a virtual line connecting the tips of the plurality of first electrode fingers 16A is defined as a second envelope curve E2. Hereinafter, the first electrode finger 16A and the second electrode finger 17A may be simply referred to as an electrode finger. The first busbar 14A and the second busbar 15A may be simply referred to as a busbar.

A region between the first envelope curve E1 and the second envelope curve E2 is an intersection region J. More specifically, a region surrounded by an end edge portion of the electrode finger in one end in an alignment direction of the plurality of electrode fingers, an end edge portion of the electrode finger in the other end in the plurality of electrode fingers, the first envelope curve E1, and the second envelope curve E2 is the intersection region J. Therefore, the first envelope curve E1 corresponds to an end edge portion of the intersection region J on the first busbar 14A side. The second envelope curve E2 corresponds to an end edge portion of the intersection region J on the second busbar 15A side. In the intersection region J, the adjacent electrode fingers overlap each other when viewed in an extending direction of the first envelope curve E1 or the second envelope curve E2.

In the first example embodiment, the intersection region J is defined by one curve region. The curve region is a region where each shape of the plurality of first electrode fingers 16A and the plurality of second electrode fingers 17A in a plan view is a curve shape. One end edge of the curve region defining the intersection region J is the first envelope curve E1. The other end edge is the second envelope curve E2. However, in the first acoustic wave resonator 1A which is the excitation angle change resonator, the plurality of electrode fingers may be curved. For example, the shape of the plurality of electrode fingers in a plan view may be a shape curved in a plurality of nodes.

An AC voltage is applied to the first IDT electrode 18A such that an acoustic wave is excited in the intersection region J. More specifically, for example, an SH mode is excited as a main mode. In this case, Rayleigh waves become unwanted waves. However, the main mode is not limited to the SH mode.

As described above, the intersection region J of the first IDT electrode 18A is a curve region. The shape of each electrode finger in a plan view in the curve region is the curve shape. Therefore, an excitation direction of an acoustic wave is not uniform in the curve region of the first IDT electrode 18A.

As shown in FIG. 3, the shape of the plurality of first electrode fingers 16A and the second electrode finger 17A of the first IDT electrode 18A in a plan view is an arc shape. Specifically, each shape of the plurality of electrode fingers in a plan view is a shape corresponding to each arc of a plurality of concentric circles. Therefore, the centers of the circles including the arcs in the shapes of the plurality of electrode fingers coincide with each other. The center is defined as a fixed point C.

The shape of the plurality of electrode fingers of the first IDT electrode 18A is not limited to the above-described example. When the intersection region J includes a curve region, the shape of the plurality of electrode fingers of the first IDT electrode 18A in a plan view may be a curve shape in the curve region. For example, the shape of the plurality of electrode fingers of the first IDT electrode 18A in a plan view may be a shape of an elliptical arc, or may be an arc and a curve shape other than the elliptical arc. Alternatively, the intersection region J does not need to include the curve region, and the shape of the plurality of electrode fingers in a plan view may be a shape curved in a plurality of nodes.

In the first example embodiment, a direction in which a portion having the curve shape of the electrode finger protrudes in an alignment direction of the plurality of electrode fingers is an outer direction. Specifically, a right direction in FIG. 3 is the outer direction of the first acoustic wave resonator 1A. A direction opposite to the outer direction is an inner direction. More specifically, a direction in which the portion having the curve shape of the electrode finger is recessed in the alignment direction of the plurality of electrode fingers is the inner direction. The left direction in FIG. 3 is the inner direction of the first acoustic wave resonator 1A. The same applies to a case where the shape of the plurality of electrode fingers in a plan view is the shape curved in the plurality of nodes. A direction in which a portion having a shape curved in the electrode finger protrudes in the alignment direction of the plurality of electrode fingers is the outer direction.

When an elliptical coefficient of a circle or ellipse including an arc in the shape of the plurality of electrode fingers is defined as α2/α1, the elliptical coefficient α2/α1 is about 1 in the first example embodiment, for example. α1 corresponds to a dimension along a direction of an axis passing through the intersection region J, in a long axis and a short axis of the ellipse. α2 corresponds to a dimension along a direction of an axis that does not pass through the intersection region J, in the long axis and the short axis of the ellipse.

As described above, the piezoelectric body layer 6 has a propagation axis. An extending direction of the propagation axis is parallel or substantially parallel to an extending direction of the two-dot chain line N in FIG. 3. The first envelope curve E1 is linear, and is inclined with respect to the propagation axis. Similarly, the second envelope curve E2 is linear, and is inclined with respect to the propagation axis. The extending direction of the first envelope curve E1 and the extending direction of the second envelope curve E2 intersect each other. The first envelope curve E1 and the second envelope curve E2 are line-symmetrically disposed with respect to a symmetry axis passing through the center of the intersection region J. In the first example embodiment, the symmetry axis is parallel or substantially parallel to the extending direction of the propagation axis.

The shape and the disposition of the first envelope curve E1 and the second envelope curve E2 are not limited to the above-described example. In the present invention, for example, at least one of the first envelope curve E1 and the second envelope curve E2 may have any shape other than the linear shape, or at least one may have the linear shape.

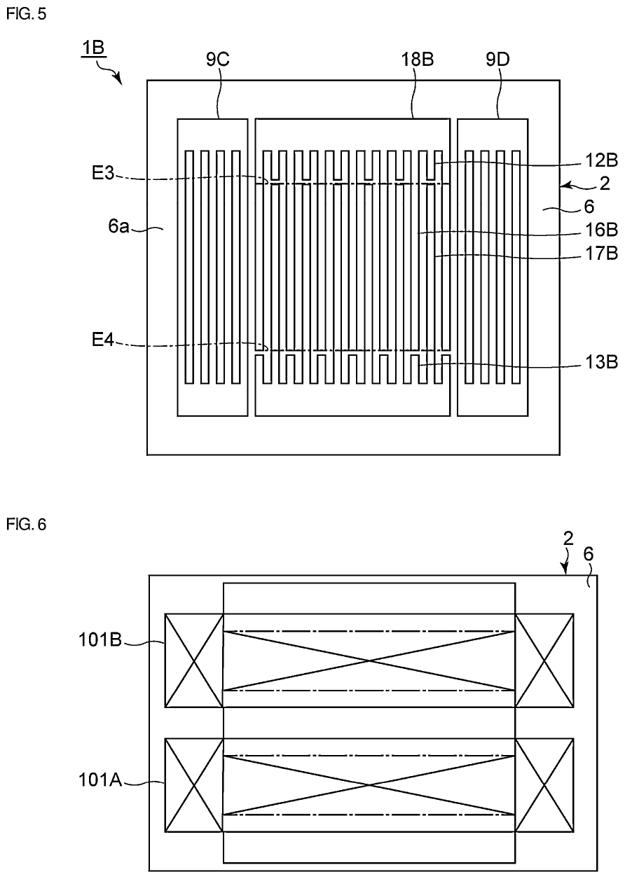

FIG. 5 is a schematic plan view of the second acoustic wave resonator in the first example embodiment.

The second acoustic wave resonator 1B shares the piezoelectric substrate 2 with the first acoustic wave resonator 1A. The second acoustic wave resonator 1B is an acoustic wave resonator that is not the excitation angle change resonator. Therefore, in the first example embodiment, the piezoelectric body layer 6 includes the propagation axis, in both of the first acoustic wave resonator 1A that is the excitation angle change resonator and the second acoustic wave resonator 1B that is not the excitation angle change resonator. The second acoustic wave resonator 1B includes a second IDT electrode 18B. The second IDT electrode 18B is provided on the first main surface 6a of the piezoelectric body layer 6 in the piezoelectric substrate 2.

The second IDT electrode 18B includes a pair of busbars and a plurality of electrode fingers. Specifically, the plurality of electrode fingers of the second IDT electrode 18B are a plurality of third electrode fingers 16B and a plurality of fourth electrode fingers 17B. The shape of the plurality of third electrode fingers 16B and the plurality of fourth electrode fingers 17B in a plan view is linear.

As in each electrode finger of the first IDT electrode 18A, each of the plurality of third electrode fingers 16B and the plurality of fourth electrode fingers 17B includes a base end portion, a tip portion, and a pair of end edge portions. Each base end portion of the plurality of third electrode fingers 16B is connected to one busbar. Each base end portion of the plurality of fourth electrode fingers 17B is connected to the other busbar. The plurality of third electrode fingers 16B and the plurality of fourth electrode fingers 17B interdigitate each other.

A virtual line formed by connecting the tips of the plurality of fourth electrode fingers 17B is defined as a third envelope curve E3. Similarly, a virtual line formed by connecting the tips of the plurality of third electrode fingers 16B is defined as a fourth envelope curve E4. The second IDT electrode 18B includes an intersection region. The intersection region is a region between the third envelope curve E3 and the fourth envelope curve E4. In the intersection region, when viewed in the extending direction of the third envelope curve E3 or the fourth envelope curve E4, adjacent electrode fingers overlap each other.

The third envelope curve E3 and the fourth envelope curve E4 are linear. The third envelope curve E3 and the fourth envelope curve E4 extend parallel to the extending direction of the propagation axis of the piezoelectric body layer 6. The second IDT electrode 18B is a so-called normal IDT electrode.

Characteristics of the first example embodiment show the following configuration. 1) The plurality of acoustic wave resonators include the excitation angle change resonator. 2) The plurality of acoustic wave resonators are connected to each other in series or in parallel, other element is not connected between the plurality of acoustic wave resonators, and the circuit of the filter device is not branched between the plurality of acoustic wave resonators. As described above, the acoustic wave device 1 of the first example embodiment is used for the filter device. In the circuit configuration of the filter device, the plurality of acoustic wave resonators correspond to divided resonators in which one resonator is divided in series. The divided resonator includes the excitation angle change resonator. In this manner, the unwanted waves can be reduced or prevented. This details will be described below along with details of the configuration of the first example embodiment and details of the excitation angle and the excitation angle change resonator.

In the intersection region J shown in FIG. 3, the excitation direction of the acoustic wave in a portion of an electrode finger in the plurality of first electrode fingers 16A and the plurality of second electrode fingers 17A is one of the following first to third directions. The first direction is a direction perpendicular or substantially perpendicular to an extending direction of the electrode finger. The second direction is a direction connecting the shortest distance between the electrode finger and the first electrode finger 16A or the second electrode finger 17A adjacent to the electrode finger. The third direction is a direction of an electric field vector generated between the electrode finger and the first electrode finger 16A or the second electrode finger 17A adjacent to the electrode finger.

Since the shape of each electrode finger in the intersection region J is the curve shape, the extending direction of one electrode finger differs for each position. In the present specification, unless otherwise specified, the extending direction of the electrode fingers having the curve shape is as follows.

First, a pair of end edge portions of each electrode finger have a curve shape. When a virtual line parallel to the extending direction of the propagation axis is drawn to connect both end edge portions in a portion of the electrode finger, the center of gravity of the portion located on the virtual line is defined as a representative point in the virtual line. Innumerable virtual lines can be drawn in the electrode finger, and there exist innumerable representative points. The extending direction of a tangent line of a curve connecting the representative points is defined as the extending direction of the electrode finger.

An angle formed by the excitation direction of the acoustic wave and the extending direction of the propagation axis of the piezoelectric body layer 6 is defined as an excitation angle θ_{C_prop}. The excitation angle change resonator in the present invention is a resonator in which the excitation angle θ_{C_prop} is changed in the intersection region J. In other words, the excitation angle θ_{C_prop} is not uniform in the intersection region J of the excitation angle change resonator.

In the first example embodiment, the extending direction of the propagation axis is parallel or substantially parallel to the extending direction of the two-dot chain line N in FIG. 3. The two-dot chain line N is a straight line passing through the fixed point C and the intersection region J. The fixed point C is defined by the shape of the plurality of electrode fingers in a plan view. Specifically, in the first example embodiment, the centers of the circles including the arcs in the shapes of the plurality of electrode fingers coincide with each other. The center is the fixed point C. In a portion indicated by the two-dot chain line N, the excitation angle θ_{C_prop} is about 0°. A portion where the excitation angle θ_{C_prop} is about 0° is linearly aligned.

Similarly, as shown by a straight line M in FIG. 3, in the first example embodiment, the excitation angle θ_{C_prop} is an angle other than 0°, and is linear even when the portions where the excitation angles θ_{C_prop} are the same or substantially the same are connected. The straight line M is a straight line passing through the fixed point C and the intersection region J.

The straight line M in FIG. 3 is an example of the straight line passing through the fixed point C and the intersection region J. That is, a portion located on the straight line M in the intersection region J is an example of a portion where the excitation angle θ_{C_prop} is the angle other than 0° and the excitation angles θ_{C_prop} are the same or substantially the same. The straight lines passing through the fixed point C and the intersection region J innumerably exist. As in the portion located on the straight line M, in a portion located on an innumerable straight line (not shown) in the intersection region J, the excitation angle θ_{C_prop} is the angle other than 0°, and the excitation angles θ_{C_prop} are the same or substantially the same. However, the excitation angles θ_{C_prop} are different from each other in the portions on the straight line. In this way, the shape of the plurality of first electrode fingers 16A and the plurality of second electrode fingers 17A in a plan view is a shape in which the portions where the excitation angles θ_{C_prop} are the angles other than 0° and the same portion are linearly aligned.

In the present specification, a positive direction of the excitation angle θ_{C_prop} is defined as a counterclockwise direction when viewed in a plan view. More specifically, a direction from the second busbar 15A side toward the first busbar 14A side is the positive direction.

When a straight line passing through the center of the intersection region J is defined as a reference line, the two-dot chain line N coincides with the reference line in the first example embodiment. The reference line does not necessarily need to extend parallel to the extending direction of the propagation axis. An angle formed by the straight line passing through the first envelope curve E1 and the fixed point C and the reference line is defined as an intersection angle θ_{C1_AP}. An angle formed by the straight line passing through the second envelope curve E2 and the fixed point C and the reference line is defined as an intersection angle θ_{C2_AP}. In this case, a relationship is expressed by θ_{C_AP2}≤θ_{C_prop}≤θ_{C_AP1}. In the first example embodiment, the absolute values of the intersection angle θ_{C_AP1} and the intersection angle θ_{C_AP2} are the same or substantially the same. Therefore, the absolute value of the excitation angle θ_{C_prop} is 0°≤|θ_{C_prop}|≤|θ_{C_AP1}|=|θ_{C_AP2}|

In the first IDT electrode 18A of the first example embodiment, the electrode finger pitch and the duty ratio are constant in the portions where the excitation angle θ_{C_prop} are the same or substantially the same. The electrode finger pitch is an inter-center distance between the first electrode finger 16A and the second electrode finger 17A which are adjacent to each other. When a wavelength defined by the electrode finger pitch of the first IDT electrode 18A is defined as λ and the electrode finger pitch is defined as p, a relationship is expressed by λ=2p.

In the first IDT electrode 18A of the first acoustic wave resonator 1A, the duty ratio is changed in accordance with the excitation angle θ_{C_prop}. Specifically, the duty ratio has a maximum value in the portion where the excitation angle θ_{C_prop} is about 0°, and decreases as the absolute value |θ_{C_prop}| of the excitation angle increases. However, the present invention is not limited thereto.

As shown in FIG. 3, the first IDT electrode 18A includes a plurality of offset electrodes. Specifically, the plurality of offset electrodes of the first IDT electrode 18A are a plurality of first offset electrodes 12A and a plurality of second offset electrodes 13A. One end of each of the plurality of first offset electrodes 12A is connected to a first busbar 14A. The first electrode finger 16A and the first offset electrode 12A are alternately aligned. One end of each of the plurality of second offset electrodes 13A is connected to a second busbar 15A. The second electrode finger 17A and the second offset electrode 13A are alternately aligned.

As in the plurality of first electrode fingers 16A and the plurality of second electrode fingers 17A, each of the plurality of first offset electrodes 12A and the plurality of second offset electrodes 13A includes a base end portion and a tip portion. The base end portions of the first electrode finger 16A and the first offset electrode 12A are portions connected to the first busbar 14A. The base end portions of the second electrode finger 17A and the second offset electrode 13A are portions connected to the second busbar 15A. The tip portion of the first electrode finger 16A and the tip portion of the second offset electrode 13A face each other with a gap interposed therebetween. The tip portion of the second electrode finger 17A and the tip portion of the first offset electrode 12A face each other with a gap interposed therebetween.

Hereinafter, the first offset electrode 12A and the second offset electrode 13A may be simply referred to as an offset electrode. Each shape of the plurality of offset electrodes in a plan view includes a curve shape portion. The plurality of first offset electrodes 12A and the plurality of second offset electrodes 13A are not necessarily needed.

A pair of reflectors 9A and a reflector 9B are provided on the piezoelectric body layer 6. The reflector 9A and the reflector 9B face each other with the first IDT electrode 18A interposed therebetween in the alignment direction of the plurality of electrode fingers of the first IDT electrode 18A.

The reflector 9A includes a pair of reflector busbars 9a and a reflector busbar 9b. The reflector busbar 9a and the reflector busbar 9b face each other. The reflector 9A includes a plurality of reflector electrode fingers 9c. Each one end of the plurality of reflector electrode fingers 9c is connected to the reflector busbar 9a. Each of the other ends of the plurality of reflector electrode fingers 9c is connected to the reflector busbar 9b. Each shape of the plurality of reflector electrode fingers 9c of the reflector 9A in a plan view includes a curve shape.

Similarly, the reflector 9B includes a pair of reflector busbars 9d and a reflector busbar 9e, and a plurality of reflector electrode fingers 9f. The first IDT electrode 18A, the reflector 9A, and the reflector 9B include a single layer metal film. Specifically, in the first example embodiment, for example, Al is used as the materials of the first IDT electrode 18A, the reflector 9A, and the reflector 9B. The materials of the first IDT electrode 18A, the reflector 9A, and the reflector 9B are not limited to the above-described example. Alternatively, the first IDT electrode 18A, the reflector 9A, and the reflector 9B may include a multilayer metal film.

As shown in FIG. 5, the second IDT electrode 18B of the second acoustic wave resonator 1B also includes the plurality of offset electrodes. Specifically, the plurality of offset electrodes of the second IDT electrode 18B are a plurality of third offset electrodes 12B and a plurality of fourth offset electrodes 13B. The shape of the plurality of third offset electrodes 12B and the plurality of fourth offset electrodes 13B in a plan view is linear.

The second acoustic wave resonator 1B includes a pair of reflector 9C and reflector 9D. The shape of each reflector electrode finger of each reflector in a plan view is linear.

In the piezoelectric body layer 6 of the acoustic wave device 1, the direction in which the propagation axis extends is the X-propagation direction. However, the present invention is not limited thereto. For example, the extending direction of the propagation axis may be a direction of about 90° X-propagation, or may be a direction perpendicular to one of the extending directions of the electrode fingers in the first IDT electrode 18A.

As shown in FIG. 4, the dielectric film 8 is provided on the piezoelectric body layer 6 to cover the first IDT electrode 18A. Since the first IDT electrode 18A is protected by the dielectric film 8, the first IDT electrode 18A is less likely to be damaged. Although not shown, the second IDT electrode 18B is also covered by the dielectric film 8. In the first example embodiment, for example, silicon oxide is provided as the material of the dielectric film 8. The material of the dielectric film 8 is not limited to the above-described example. In the first example embodiment, the thickness of the dielectric film 8 is constant. The dielectric film 8 is not necessarily needed.

As described above, the unwanted waves can be reduced or prevented since the plurality of acoustic wave resonators of the acoustic wave device 1 include the excitation angle change resonator. This will be described below by comparing the first example embodiment and a comparative example.

As shown in FIG. 6, the comparative example is different from the first example embodiment in that both a first acoustic wave resonator 101A and a second acoustic wave resonator 101B are normal acoustic wave resonators. That is, the plurality of acoustic wave resonators of the comparative example do not include the excitation angle change resonator. Phase characteristics are compared between the acoustic wave device having the configuration of the first example embodiment and the acoustic wave device of the comparative example.

Design parameters of the acoustic wave resonator having the configuration of the first acoustic wave resonator 1A which is the excitation angle change resonator are as follows. Here, a dimension of the offset electrode along a connecting direction of the base end portion and the tip portion is defined as the length of the offset electrode. A dimension of a gap between the tip portion of the electrode finger and the tip portion of the offset electrode along a direction in which the electrode finger and the offset electrode face each other is defined as a gap length. In the first example embodiment, the gap lengths are the same or substantially the same in the gap between the tip portion of the second electrode finger 17A and the tip portion of the first offset electrode 12A and the gap between the tip portion of the first electrode finger 16A and the tip portion of the second offset electrode 13A.
Support Substrate 4: Material_Si, Surface Orientation_(111), ψ at Euler Angles (φ, θ, ψ) about 73°
First Layer 5a of Intermediate Layer 5: Material_SiN, Thickness about 0.15λ
Second Layer 5b of Intermediate Layer 5: Material_SiO₂, Thickness about 0.15λ
Piezoelectric Body Layer 6: Material_Rotational Y-cut 55° X-propagation LiTaO₃, Thickness about 0.2λ
First IDT Electrode 18A: Material_Al, Thickness about 0.05λ
Dielectric Film 8: Material_SiO₂, Thickness about 0.015λ
Intersection Angle θ_{C1_AP}: about 5°
Intersection Angle θ_{C2_AP}: about −5°
Wavelength λ: about 2 μm in the portion where the Excitation Angle θ_{C_prop} is about 0°
Number of Pairs of Electrode Fingers of First IDT Electrode 18A: 80 pairs
Duty ratio: about 0.5 in the portion where the excitation angle θ_{C_prop} is about 0°, and the duty ratio decreases as the absolute value |θ_{C_prop}| of the excitation angle increases.
Gap Length: about 0.135λ
Length of Offset Electrode: about 3.5λ
Reflector 9A and Reflector 9B: Number of Pairs of Reflector Electrode Fingers_20 pairs

In the acoustic wave resonator having the configuration of the second acoustic wave resonator 1B, the duty ratio is about 0.5, and is constant. In each of the acoustic wave resonators of the comparative example, the duty ratio is about 0.5, and is constant.

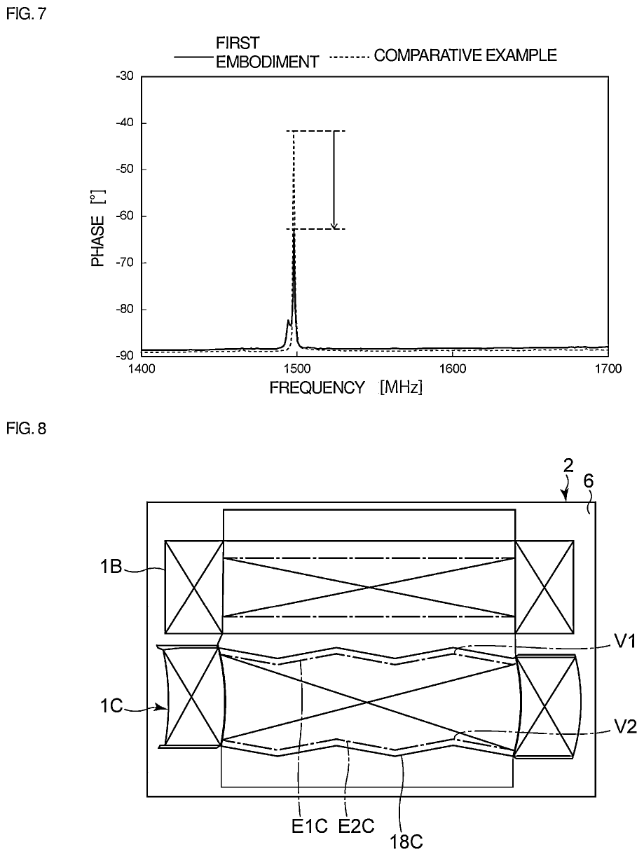

FIG. 7 is a view showing the phase characteristics in the vicinity of the frequency at which the unwanted waves are generated in the first example embodiment and the comparative example.

As shown in FIG. 7, it can be understood that the Rayleigh waves as the unwanted waves can be further reduced or prevented in the first example embodiment, compared to the comparative example. In this way, when the acoustic wave devices of the first example embodiment and the comparative example have the same number of the acoustic wave resonators, the unwanted waves can be further reduced or prevented in the first example embodiment, compared to the comparative example. Therefore, in the first example embodiment, in order to reduce or prevent the unwanted waves, it is not necessary to increase the number of the acoustic wave resonators. Therefore, in the first example embodiment, the unwanted waves can be reduced or prevented without increasing the size of the filter device to be used.

Since the plurality of acoustic wave resonators of the acoustic wave device 1 include the first acoustic wave resonator 1A as the excitation angle change resonator, the unwanted waves can be reduced or prevented in the acoustic wave device 1. The reason is as follows.

In the intersection region J of the first acoustic wave resonator 1A shown in FIG. 3, linear portions where the excitation angles θ_{C_prop} are the angles other than 0° and the excitation angle θ_{C_prop} are the same or substantially the same are innumerably aligned in a direction in which the first busbar 14A and the second busbars 15A face each other. The excitation angles θ_{C_prop} are different from each other in the above-described linear portions. In the portions where the excitation angles θ_{C_prop} are different from each other, propagation characteristics of the unwanted waves are different from each other. In this manner, the unwanted waves can be dispersed, and the unwanted waves can be effectively reduced or prevented. In particular, the unwanted waves outside the band, such as the Rayleigh waves, can be reduced or prevented. In the present specification, the outside of the band in the acoustic wave device means a lower band side of a resonant frequency and a higher band side of an anti-resonant frequency.

In the first acoustic wave resonator 1A, the first envelope curve E1 and the second envelope curve E2 extend inclined with respect to the propagation axis of the piezoelectric body layer 6. In this manner, a transverse mode can be reduced or prevented. The transverse mode is the unwanted waves generated between the resonant frequency and the anti-resonant frequency. However, the first envelope curve E1 and the second envelope curve E2 may extend parallel or substantially parallel to the extending direction of the propagation axis.

In the first example embodiment, an example in which the second acoustic wave resonator 1B is the acoustic wave resonator that is not the excitation angle change resonator has been described. In the first example embodiment, the number of the excitation angle change resonators is one. However, the acoustic wave device 1 may include two or more excitation angle change resonators. All of the acoustic wave resonators of the acoustic wave device 1 may be the excitation angle change resonators.

Hereinafter, details of a relationship between the acoustic wave device according to the present invention and the filter device for which the acoustic wave device is used will be described with reference to FIG. 2.

As shown in FIG. 2, the filter device 10 is a ladder filter.

The filter device 10 includes an input terminal 7A, an output terminal 7B, a plurality of series arm resonators, and a plurality of parallel arm resonators. In a circuit configuration of the filter device 10, a series arm S, a plurality of parallel arms P, and a plurality of nodes D are provided. The series arm S is a path connecting the input terminal 7A and the output terminal 7B. The series arm S is provided with each series arm resonator. On the other hand, each parallel arm P is a path that branches from the series arm S to each ground terminal. Each parallel arm P is provided with each parallel arm resonator. On the other hand, the node D is a connection point between the series arm S and the parallel arm P.

The filter device 10 includes a plurality of series arm resonator units. The series arm resonator unit is one series arm resonator or a group of a plurality of series arm resonators connected to each other in series or in parallel without using the node D. More specifically, the series arm resonator unit is a portion provided with one or more series arm resonators between the input terminal 7A and the node D, between the nodes D, or between the node D and the output terminal 7B.

In the example shown in FIG. 2, the acoustic wave device 1 of the first example embodiment is the series arm resonator unit. The first acoustic wave resonator 1A and the second acoustic wave resonator 1B are two series arm resonators in one series arm resonator unit. The series arm resonator unit includes only one or more series arm resonators. Therefore, other elements are not disposed between the plurality of acoustic wave resonators of the acoustic wave device 1. The node D or other branch points are not disposed between the plurality of series arm resonators in one series arm resonator unit. Therefore, the circuit of the filter device 10 is not branched between the plurality of acoustic wave resonators of the acoustic wave device 1.

The filter device 10 includes a plurality of series arm resonator units other than the acoustic wave device 1. Specifically, the series arm resonator units are a series arm resonator unit S2 and a series arm resonator unit S3. From the input terminal 7A side, the acoustic wave device 1, the series arm resonator unit S2, and the series arm resonator unit S3 are connected to each other in series in this order. Each of the series arm resonator unit S2 and the series arm resonator unit S3 includes one series arm resonator.

In the filter device 10, the acoustic wave device 1 is the series arm resonator unit located closest to the input terminal 7A side. However, the disposition of the acoustic wave device 1 in the filter device 10 is not limited to the above-described example. For example, the acoustic wave device 1 may be the series arm resonator unit located closest to the output terminal 7B side in the filter device 10, or may be the series arm resonator unit which is not located at any position closest to the input terminal 7A and closest to the output terminal 7B.

The filter device 10 includes a plurality of parallel arm resonator units. The parallel arm resonator unit is one parallel arm resonator or a group of the plurality of parallel arm resonators connected to each other in series or in parallel in the parallel arm P. For example, the parallel arm resonator unit may be a portion including a plurality of divided parallel arm resonators. Hereinafter, the series arm resonator unit and the parallel arm resonator unit may be collectively and simply referred to as a resonator unit.

Specifically, the plurality of parallel arm resonator units of the filter device 10 are a parallel arm resonator unit P1 and a parallel arm resonator unit P2. All of the parallel arm resonator units of the filter device 10 include one parallel arm resonator. The parallel arm resonator unit P1 is connected between the node D between the acoustic wave device 1 and the series arm resonator unit S2 and the ground potential. The parallel arm resonator unit P2 is connected between the node D between the series arm resonator unit S2 and the series arm resonator unit S3 and the ground potential.

The acoustic wave device 1 may be the parallel arm resonator unit corresponding to the parallel arm resonator unit P1. In this case, the first acoustic wave resonator 1A and the second acoustic wave resonator 1B are two parallel arm resonators in one parallel arm resonator unit. The parallel arm resonator unit includes only one or more parallel arm resonators. Therefore, other elements are not disposed between the plurality of acoustic wave resonators of the acoustic wave device 1. The node D or other branch points are not disposed between the plurality of parallel arm resonators in one parallel arm resonator unit. Therefore, even when the acoustic wave device 1 corresponds to the parallel arm resonator unit P1, the circuit of the filter device 10 is not branched between the plurality of acoustic wave resonators.

That is, the acoustic wave device according to the present invention is the resonator unit in the filter device. The acoustic wave device which is the resonator unit includes the plurality of acoustic wave resonators, and the plurality of acoustic wave resonators include at least one of the excitation angle change resonators. In the acoustic wave device, the plurality of acoustic wave resonators may be connected to each other in series, or may be connected to each other in parallel.

In the first example embodiment, the resonant frequencies of the main mode of the first acoustic wave resonator 1A substantially coincide with each other in all of the intersection regions J. Specifically, in the first acoustic wave resonator 1A, the duty ratio is changed in accordance with the excitation angle θ_{C_prop}. In this manner, the resonant frequencies substantially coincide with each other in all of the intersection regions J.

In the portions where the excitation angles θ_{C_prop} of the excitation angle change resonators are different from each other, relationships between the resonant frequencies and the anti-resonant frequencies of the main mode and the unwanted waves are different from each other. In the first acoustic wave resonator 1A which is the excitation angle change resonator, the resonant frequencies of the main mode coincide with each other in all of the intersection regions J. Therefore, the frequencies of the unwanted waves are different from each other. In this manner, the unwanted waves outside the band are dispersed. Therefore, the unwanted waves outside the band, such as Rayleigh waves, for example, can be further reduced or prevented.

In addition, since the resonant frequencies in the intersection region J substantially coincide with each other, the main mode is preferably excited. Therefore, resonance characteristics can be more reliably improved. In this manner, the filter characteristics of the filter device to be used can be more reliably improved.

Similarly, when the anti-resonant frequencies of the main mode in the excitation angle change resonator substantially coincide with each other in all of the intersection regions J, the unwanted waves outside the band can be dispersed, and the unwanted waves outside the band can be further reduced or prevented. In addition, the resonance characteristics of the excitation angle change resonator can be more reliably improved.

In the present specification, description that one frequency and the other frequency substantially coincide with each other means that the absolute value of the difference between both frequencies is equal to or smaller than 2% of a reference frequency. The reference frequency refers to a frequency when the excitation angle θ_{C_prop} is about 0°.

In the intersection region J of the excitation angle change resonator, it is preferable that the absolute value of the difference between the highest resonant frequency and the lowest resonant frequency of the main mode is, for example, equal to or smaller than about 1% of the reference frequency. Alternatively, in the intersection region J of the excitation angle change resonator, it is preferable that the absolute value of the difference between the highest anti-resonant frequency and the lowest anti-resonant frequency of the main mode is, for example, equal to or smaller than about 1% of the reference frequency. In this manner, resonance characteristics can be more reliably improved.

In the first example embodiment, in the intersection region J of the first acoustic wave resonator 1A which is the excitation angle change resonator, the resonant frequencies substantially coincide with each other. The first acoustic wave resonator 1A and the second acoustic wave resonator 1B are divided resonators divided in series. In the present specification, a plurality of divided resonators divided in series are a plurality of acoustic wave resonators of the same resonator unit, are connected to each other in series, and are a plurality of acoustic wave resonators in which a difference between the resonant frequencies is, for example, about 2% or smaller. On the other hand, in the present specification, a plurality of divided resonators divided in parallel are a plurality of acoustic wave resonators of the same resonator unit, are connected to each other in parallel, and are a plurality of acoustic wave resonators in which the difference between the resonant frequencies is, for example, about 2% or smaller.

More specifically, when the resonant frequency of the excitation angle change resonator is compared with the resonant frequency of other acoustic wave resonators, the resonant frequency of a portion where the excitation angle θ_{C_prop} is about 0° in the intersection region J may be compared with the resonant frequency of other acoustic wave resonators. Hereinafter, the resonant frequency of the portion where the excitation angle θ_{C_prop} is about 0° in the intersection region J of the excitation angle change resonator is defined as a reference resonant frequency.

For example, in the first example embodiment, the resonant frequency of the first acoustic wave resonator 1A which is the excitation angle change resonator may be compared with the resonant frequency of the second acoustic wave resonator 1B which is not the excitation angle change resonator. A difference between the reference resonant frequency of the first acoustic wave resonator 1A and the resonant frequency of the second acoustic wave resonator 1B is, for example, about 2% or smaller with respect to both of the reference resonant frequency and the resonant frequency. Therefore, the first acoustic wave resonator 1A and the second acoustic wave resonator 1B are the divided resonators.

In an example embodiment of the present invention, at least one of the plurality of acoustic wave resonators of the acoustic wave device may be the excitation angle change resonator. Hereinafter, a preferable configuration provided in at least one excitation angle change resonator in the present invention will be described. In describing the excitation angle change resonator below, reference numerals in the configuration of the first acoustic wave resonator 1A may be used.

It is preferable that the resonant frequencies or the anti-resonant frequencies of the main mode in at least one of the excitation angle change resonators substantially coincide with each other in all of the intersection regions J. In this manner, the unwanted waves outside the band can be dispersed, and the unwanted waves outside the band can be further reduced or prevented. In addition, since the resonant frequencies or the anti-resonant frequencies in the intersection region J substantially coincide with each other, the main mode is preferably excited. Therefore, resonance characteristics can be more reliably improved. In this manner, the filter characteristics of the filter device to be used can be more reliably improved.

It is preferable that at least two of the plurality of acoustic wave resonators are the excitation angle change resonators, and the acoustic wave resonators are the divided resonators divided in series or divided in parallel. Specifically, in this case, in each of the intersection regions J of at least two of the excitation angle change resonators, the resonant frequencies substantially coincide with each other. The following relationship is established between at least two of the excitation angle change resonators. The relationship is a relationship in which a difference in the reference resonant frequency between the two excitation angle change resonators in which the resonant frequencies substantially coincide with each other in the intersection region J is about 2% or smaller with respect to the reference resonant frequency of any of the two excitation angle change resonators, for example.

In this manner, the acoustic wave resonators having the desired resonant frequency or the desired anti-resonant frequency are divided in series or divided in parallel. Therefore, the applied power can be dispersed. Therefore, the acoustic wave resonators having the desired resonant frequency or the desired anti-resonant frequency are less likely to be damaged.

However, the plurality of acoustic wave resonators of the acoustic wave device according to the present invention may be the resonators corresponding to the disposition of the divided resonators, as a circuit configuration. For example, the following relationship may be established between at least two of the excitation angle change resonators. The relationship is a relationship in which the difference in the reference resonant frequency between the two excitation angle change resonators whose resonant frequencies substantially coincide with each other in the intersection region J is, for example, larger than about 2% with respect to the reference resonant frequency of any excitation angle change resonator.

It is preferable that at least one of the plurality of acoustic wave resonators is not the excitation angle change resonator, at least one of the plurality of acoustic wave resonators is the excitation angle change resonator, and the acoustic wave resonators are the divided resonators divided in series or divided in parallel. Specifically, in this case, in the intersection region J of at least one of the excitation angle change resonators, the resonant frequencies substantially coincide with each other. The following relationship is established in at least one of the excitation angle change resonators and at least one of the acoustic wave resonators that are not the excitation angle change resonators. The relationship is a relationship in which the difference between the reference resonant frequency of the excitation angle change resonators whose resonant frequencies substantially coincide with each other in the intersection region J and the resonant frequency of the acoustic wave resonators that are not the excitation angle change resonators is, for example, equal to or smaller than about 2% with respect to any of the reference resonant frequency and the resonant frequency.

In this case as well, the acoustic wave resonators having the desired resonant frequency or the desired anti-resonant frequency are divided in series or divided in parallel. Therefore, the applied power can be dispersed. Therefore, the acoustic wave resonators having the desired resonant frequency or the desired anti-resonant frequency are less likely to be damaged.

On the other hand, the following relationship may be established in at least one of the excitation angle change resonators and at least one of the acoustic wave resonators that are not the excitation angle change resonators. The relationship is a relationship in which the difference between the reference resonant frequency of the excitation angle change resonators whose resonant frequencies substantially coincide with each other in the intersection region J and the resonant frequency of the acoustic wave resonators that are not the excitation angle change resonators is, for example, larger than about 2% with respect to any of the reference resonant frequency and the resonant frequency.

In the first example embodiment, in the first acoustic wave resonator 1A, the duty ratio is changed in accordance with the excitation angle θ_{C_prop}. In this manner, the resonant frequencies substantially coincide with each other in all of the intersection regions J. However, the present invention is not limited thereto.

For example, in at least one of the excitation angle change resonators, it is preferable that at least one of the duty ratio, the electrode finger pitch, and the thickness of the plurality of first electrode fingers 16A and the plurality of second electrode fingers 17A is changed in accordance with the excitation angle θ_{C_prop}. It is preferable that at least one of the parameters is changed in accordance with the excitation angle θ_{C_prop} such that the resonant frequencies or the anti-resonant frequencies substantially coincide with each other in at least a portion of the intersection region J. It is more preferable that at least one of the parameters is changed in accordance with the excitation angle θ_{C_prop} such that the resonant frequencies or the anti-resonant frequencies substantially coincide with each other in all of the intersection regions J. In this manner, resonance characteristics of the excitation angle change resonator can be more reliably improved.

Alternatively, when the thickness of the intermediate layer 5 inside the piezoelectric substrate 2 affects the frequency, the parameter may be changed in the intersection region J in accordance with the excitation angle θ_{C_prop}. As in the first example embodiment, when the dielectric film 8 is provided on the piezoelectric substrate 2 to cover the first IDT electrode 18A, the thickness of the dielectric film 8 may be changed in the intersection region J in accordance with the excitation angle θ_{C_prop}. The plurality of parameters in the parameters of the first IDT electrode 18A or the parameters other than the first IDT electrode 18A may be changed in the intersection region J in accordance with the excitation angle θ_{C_prop}. In these cases, the resonant frequencies or the anti-resonant frequencies can substantially coincide with each other in at least a portion or all of the intersection regions J.

It is preferable that at least one of the electrode finger pitch and the duty ratio is constant in the portions where the excitation angles θ_{C_prop} are the same or substantially the same in the first IDT electrode 18A of at least one of the excitation angle change resonators. It is more preferable that both of the electrode finger pitch and the duty ratio are constant in the portion where the excitation angle θ_{C_prop} is the same or substantially the same. In this manner, resonance characteristics of the excitation angle change resonator can be more reliably improved.

As in the first example embodiment, when the shape of the plurality of electrode fingers of the first IDT electrode 18A is the arc shape in a plan view, it is preferable to use the following configuration.

It is preferable that the shape of the plurality of first offset electrodes 12A and the plurality of second offset electrodes 13A in a plan view is the arc shape. It is more preferable that each shape of the plurality of first offset electrodes 12A and the plurality of second offset electrodes 13A in a plan view are shapes corresponding to each arc in a plurality of concentric circles. In this case, the centers of the circles including the arcs in the shapes of the plurality of offset electrodes coincide with each other. More specifically, in the first example embodiment, the centers of the circles including the arcs in the shapes of the plurality of electrode fingers and the plurality of offset electrodes coincide with each other. In this manner, a leakage from the intersection region J of the main mode can be effectively reduced or prevented.

It is preferable that each shape of the plurality of reflector electrode fingers of the reflector 9A and the reflector 9B in a plan view is the shape corresponding to each arc of the plurality of concentric circles. It is more preferable that the centers of the circles including the arcs in the shapes of the plurality of electrode fingers of the first IDT electrode 18A and the plurality of reflector electrode fingers of each reflector coincide with each other. In this manner, resonance characteristics can be more reliably improved.

The shape of the plurality of electrode fingers in a plan view may include an elliptical arc shape. More specifically, in this case, each shape of the plurality of electrode fingers in a plan view includes a shape corresponding to each elliptical arc of a plurality of ellipses whose centers of gravity are located at the same position. The center of gravity here is the center of the two foci of the ellipse. In this case, as in the first example embodiment, the unwanted waves outside the band can be reduced or prevented in the acoustic wave device. When the shape including the arc in the shape of the plurality of electrode fingers is the ellipse, an elliptical coefficient α2/α1 is other than about 1.

When the shape of the plurality of electrode fingers in a plan view includes the elliptical arc, it is preferable that the shape of the plurality of offset electrodes in a plan view also includes the elliptical arc. In this case, it is preferable that the centers of gravity of the ellipses including the elliptical arcs in the shapes of the plurality of electrode fingers and the plurality of offset electrodes coincide with each other. In this manner, a leakage from the intersection region J of the main mode can be effectively reduced or prevented.

When the shape of the plurality of electrode fingers in a plan view includes the elliptical arc, it is preferable that the shape of the plurality of reflector electrode fingers of each reflector in a plan view also includes the elliptical arc. In this case, it is preferable that the centers of gravity of the ellipses including the elliptical arcs in the shapes of the plurality of electrode fingers and the plurality of reflector electrode fingers coincide with each other. In this manner, resonance characteristics can be more reliably improved.

Hereinafter, examples of materials of respective members in the piezoelectric substrate 2 will be described.

As a material of the support substrate 4 shown in FIG. 4, for example, a piezoelectric body such as aluminum nitride, lithium tantalate, lithium niobate, and crystal, ceramic such as alumina, sapphire, magnesia, silicon nitride, silicon carbide, zirconia, cordierite, mullite, steatite, forsterite, spinel, and sialon, a dielectric such as aluminum oxide, silicon oxynitride, diamond-like carbon (DLC), and diamond, or a semiconductor such as silicon, and alternatively, a material having the above-described materials as the main components can be used. The above-described spinel includes, for example, an aluminum compound containing one or more elements selected from Mg, Fe, Zn, and Mn, and oxygen. Examples of the above-described spinel can include MgAl₂O₄, FeAl₂O₄, ZnAl₂O₄, and MnAl₂O₄. It is preferable to use, for example, high-resistance silicon for the support substrate 4. It is preferable that volume resistivity of the material of the support substrate 4 is, for example, equal to or higher than about 1000 Ω·cm. In the first example embodiment, for example, the high-resistance silicon is used as the material of the support substrate 4.

The first layer 5a of the intermediate layer 5 is a high acoustic velocity film. The high acoustic velocity film is a film having a relatively high acoustic velocity. More specifically, the acoustic velocity of the bulk wave propagating through the high acoustic velocity film is higher than the acoustic velocity of the acoustic wave propagating through the piezoelectric body layer 6. As a material of the first layer 5a which is the high acoustic velocity film, for example, a piezoelectric body such as aluminum nitride, lithium tantalate, lithium niobate, and crystal, ceramic such as alumina, sapphire, magnesia, silicon nitride, silicon carbide, zirconia, cordierite, mullite, steatite, forsterite, spinel, and sialon, a dielectric such as aluminum oxide, silicon oxynitride, diamond-like carbon (DLC), and diamond, or a semiconductor such as silicon, and alternatively, a material including the above-described materials as the main components can be used. The above-described spinel includes, for example, an aluminum compound containing one or more elements selected from Mg, Fe, Zn, and Mn, and oxygen. Examples of the above-described spinel can include MgAl₂O₄, FeAl₂O₄, ZnAl₂O₄, and MnAl₂O₄. In the first example embodiment, the silicon nitride is used as the material of the first layer 5a.

The second layer 5b of the intermediate layer 5 is a low acoustic velocity film. The low acoustic velocity film is a film having a relatively low acoustic velocity. More specifically, the acoustic velocity of the bulk wave propagating through the low acoustic velocity film is lower than the acoustic velocity of the bulk wave propagating through the piezoelectric body layer 6. As a material of the second layer 5b which is the low acoustic velocity film, for example, a dielectric such as a compound obtained by adding fluorine, carbon, or boron to glass, silicon oxide, silicon oxynitride, lithium oxide, tantalum oxide, or silicon oxide, or a material having the above-described materials as the main components can be used. In the first example embodiment, for example, the silicon oxide is used as the material of the second layer 5b.

As the material of the piezoelectric body layer 6 shown in FIG. 4, for example, lithium tantalate, lithium niobate, zinc oxide, aluminum nitride, crystal, or lead zirconate titanate (PZT) can also be used. As the material of the piezoelectric body layer 6, it is preferable to use, for example, lithium tantalate or lithium niobate. In the first example embodiment, the lithium tantalate is used as the material of the piezoelectric body layer 6.

In the first example embodiment, in the piezoelectric substrate 2, the first layer 5a defining and functioning as the high acoustic velocity film, the second layer 5b defining and functioning as the low acoustic velocity film, and the piezoelectric body layer 6 are laminated in this order. In this manner, energy of the acoustic wave can be effectively confined on the piezoelectric body layer 6 side.

As the materials of the first IDT electrode 18A, the second IDT electrode 18B, and each reflector, for example, one or more metals selected from a group consisting of Ti, Mo, Ru, W, Al, Pt, Ir, Cu, Cr, and Sc may be used. The first IDT electrode 18A, the second IDT electrode 18B, and each reflector may include a single layer metal film, or may include a multilayer metal film. In the first example embodiment, for example, Al is used as the materials of the first IDT electrode 18A, the second IDT electrode 18B, and each of the reflectors.

In the present specification, the main component means a component whose occupied ratio exceeds 50% by weight. The material of main component may exist in any one state of single crystal, polycrystal, and amorphous, or in a mixed state thereof.

Hereinafter, 1 to ninth modified examples of the first example embodiment, which are different from the first example embodiment only in the configuration of the first acoustic wave resonator, will be described. As in the first example embodiment, in the first to ninth modified examples, the unwanted waves outside the band can be reduced or prevented.

FIG. 8 is a schematic plan view of the acoustic wave device according to the first modified example of the first example embodiment.

A first envelope curve E1C in a first acoustic wave resonator 1C includes a plurality of portions inclined with respect to the propagation axis of the piezoelectric body layer 6. The first envelope curve E1C includes a plurality of bending portions V1. More specifically, the bending portion is a portion where the extending direction of the envelope curve is changed. In the present modified example, the shape of the first envelope curve E1C is a wavy shape in which the adjacent bending portions V1 are connected to each other by a straight line. The shape of the first envelope curve E1C may be a wavy shape in which the adjacent bending portions V1 are connected to each other by a curve.

Similarly, a second envelope curve E2C also includes a plurality of portions inclined with respect to the propagation axis. The second envelope curve E2C includes a plurality of bending portions V2. The shape of the second envelope curve E2C is a wavy shape in which the adjacent bending portions V2 are connected to each other by a straight line. The shape of the second envelope curve E2C may be a wavy shape in which the adjacent bending portions V2 are connected to each other by a curve.

In this way, in the present modified example, both of the first envelope curve E1C and the second envelope curve E2C include the plurality of bending portions. However, at least one of the first envelope curve E1C and the second envelope curve E2C may include at least one bending portion.

The first IDT electrode 18C includes a plurality of segments when the electrode finger passing through the bending portion V1 of the first envelope curve E1C is set as a boundary. The plurality of segments are aligned in the extending direction of the propagation axis. Specifically, the first IDT electrode 18C includes five segments.

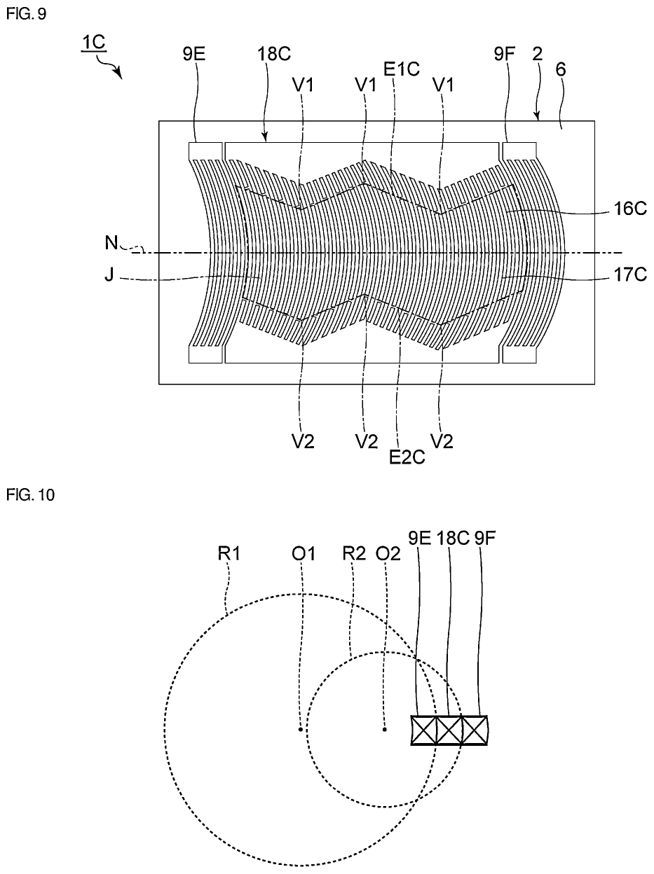

FIG. 9 is a schematic plan view of the first acoustic wave resonator according to the first modified example of the first example embodiment. FIG. 9 schematically shows four segments.

A portion including a portion located on the first envelope curve E1C in the first electrode finger 16C and adjacent to the tip portion of one second electrode finger 17C is an adjacent portion of the first electrode finger 16C. A portion including a portion located on the second envelope curve E2C in the second electrode finger 17C and adjacent to the tip portion of one first electrode finger 16C is an adjacent portion of the second electrode finger 17C. A portion in a range of approximately 1λ along the extending direction of the electrode finger from the tip of the electrode finger is the tip portion of the electrode finger. A range of the adjacent portion is also the range of approximately 1λ along the extending direction of the electrode finger. For example, an electrode finger pitch serving as a reference for the range of the tip portion and the adjacent portion may be a narrowest electrode finger pitch in the portion where the excitation angle θ_{C_prop} is 0°.

In the first acoustic wave resonator 1C serving as the excitation angle change resonator of the present modified example, the shape of the plurality of first electrode fingers 16C and the plurality of second electrode fingers 17C in a plan view is a shape in which the curvature is gently changed. Specifically, the shape of the plurality of first electrode fingers 16C and the plurality of second electrode fingers 17C in a plan view is a shape that can be approximated to the arc. In the intersection region J, the excitation direction and the excitation angle θ_{C_prop} of the acoustic wave are not uniform.

However, for example, the shape of the plurality of first electrode fingers 16C and the plurality of second electrode fingers 17C in a plan view may be a shape that can be approximated to the elliptical arc. The shape of each electrode finger in a plan view does not need to be the shape that can be approximated to the arc or the elliptical arc. In this case, for example, the shape of each electrode finger in a plan view may be a shape of a parabola that cannot be approximated to the arc and the elliptical arc.

It is preferable that the shapes of all of the electrode fingers in the first IDT electrode 18C in a plan view are curve shapes which are different from each other. The example will be specifically described as three types of examples. As a first type example, it is preferable that the curvatures are different from each other between the tip portions located on the first envelope curve E1C side, between the adjacent portions, or between the tip portion and the adjacent portion, in all of the first electrode fingers 16C and all of the second electrode fingers 17C. More specifically, it is preferable that the curvatures are different from each other between the tip portions of all of the second electrode fingers 17C, between the adjacent portions of all of the first electrode fingers 16C, and between the tip portions of all of the second electrode fingers 17C and the adjacent portions of all of the first electrode fingers 16C.

As a second type example, it is preferable that the curvatures are different from each other between the tip portions located on the second envelope curve E2C side, between the adjacent portions, or between the tip portion and the adjacent portion, in all of the first electrode fingers 16C and all of the second electrode fingers 17C. More specifically, it is preferable that the curvatures are different from each other between the tip portions of all of the first electrode fingers 16C, between the adjacent portions of all of the second electrode fingers 17C, and between the tip portions of all of the first electrode fingers 16C and the adjacent portions of all of the second electrode fingers 17C.

As a third type example, it is preferable that the curvatures are different from each other between the portions located in the portions where the excitation angle θ_{C_prop} is 0° in all of the first electrode fingers 16C and all of the second electrode fingers 17C. In this way, since the shapes of all of the electrode fingers of the first IDT electrode 18C in a plan view are the curve shapes which are different from each other, the unwanted waves can be more reliably and effectively reduced or prevented.

In the present modified example, all of the three type examples are satisfied. However, in at least one set of electrode fingers in the plurality of first electrode fingers 16C and the plurality of second electrode fingers 17C, the curvatures may be different from each other between the tip portions located on the first envelope curve E1C side, between the adjacent portions, or between the tip portion and the adjacent portion.

As in the first example embodiment, in the present modified example, the intersection region J is formed by one curve region. In the curve region, the shape of the plurality of electrode fingers in a plan view is a curve that is not the arc or the elliptical arc. The shape of the plurality of electrode fingers in a plan view is a shape that can be approximated to the arc. In other words, the shape of the plurality of electrode fingers is in a state where the shape appears to be approximated to the arc when viewed in a plan view. In addition, the shapes of the plurality of electrode fingers in a plan view are curve shapes which are different from each other. Therefore, a relationship shown in FIG. 10 is established.

FIG. 10 is a schematic plan view showing a circle including the arc when the shape of the electrode finger in a plan view of the first IDT electrode in the first modified example of the first example embodiment is approximated to the arc.

In FIG. 10, two circles R1 and a circle R2 are indicated by a broken line. The circle R1 and the circle R2 are circles including each arc when the shapes of the two electrode fingers different from each other in a plan view are approximated by the arc. A position of a center O1 of the circle R1 and a position of a center O2 of the circle R2 are different from each other.

In the curve region, it is preferable that positions of the centers of the circles including the arcs are different from each other, when the shapes of all of the first electrode fingers 16C and all of the second electrode fingers 17C in a plan view are approximated to the arcs. In this case, as described above, the shapes of all of the electrode fingers in the first IDT electrode 18C in the plan view are the curve shapes which are different from each other. In this manner, the unwanted waves can be more reliably and effectively reduced or prevented. However, in the curve region, the positions of the centers of the circles including the arcs may be different from each other, when the shape of at least one set of electrode fingers in the plurality of first electrode fingers 16C and the plurality of second electrode fingers 17C in a plan view is approximated by the arc.

In the curve region, the shape of the plurality of first electrode fingers 16C and the plurality of second electrode fingers 17C in a plan view may be the shape that can be approximated to the elliptical arc. In this case, in the curve region, it is preferable that the positions of the centers of gravity of the ellipses including the elliptical arcs are different from each other, when the shapes of all of the first electrode fingers 16C and all of the second electrode fingers 17C in a plan view are approximated to the elliptical arc. However, in the curve region, the positions of the centers of gravity of the ellipses including the elliptical arcs may be different from each other, when the shape of at least one set of electrode fingers in the plurality of first electrode fingers 16C and the plurality of second electrode fingers 17C in a plan view is approximated to the elliptical arc.

Returning to FIG. 8, the excitation angle θ_{C_prop} of the end portion of the first envelope curve E1C or the portion located in the bending portion V1 is defined as an excitation angle θ_{C_AP1_m} on the first envelope curve. m is a natural number. The excitation angle θ_{C_AP1_m} on the first envelope curve can be defined for the end portion of the first envelope curve E1C or each of the bending portions V1. Specifically, m in the excitation angle θ_{C_AP1_m} on the first envelope curve is sequentially set to 1, 2, 3, and so on from the end portion and the bending portion V1 on the inner side of the IDT electrode 18C. In this way, a numerical value of m is smaller in the excitation angle θ_{C_AP1_m} on the first envelope curve of the portion located on the inner side. For example, the excitation angle θ_{C_prop} of the portion located in the end portion on the inner side is an excitation angle θ_{C_AP2_m} on the first envelope curve. The excitation angle θ_{C_prop} in the innermost bending portion V1 is an excitation angle θ_{C_AP_2} on the first envelope curve.

Similarly, the excitation angle θ_{C_prop} of the end portion of the second envelope curve E2C or the portion located in the bending portion V2 is defined as an excitation angle θ_{C_AP2_m} on the second envelope curve. A numerical value of m is smaller in the excitation angle θ_{C_AP2_m} on the second envelope curve of the portion located on the inner side.

The shape of the reflector 9E and the reflector 9F has a shape corresponding to the shape of the first IDT electrode 18C. The shape of each reflector electrode finger of the reflector 9E and the reflector 9F in a plan view is a curve shape.

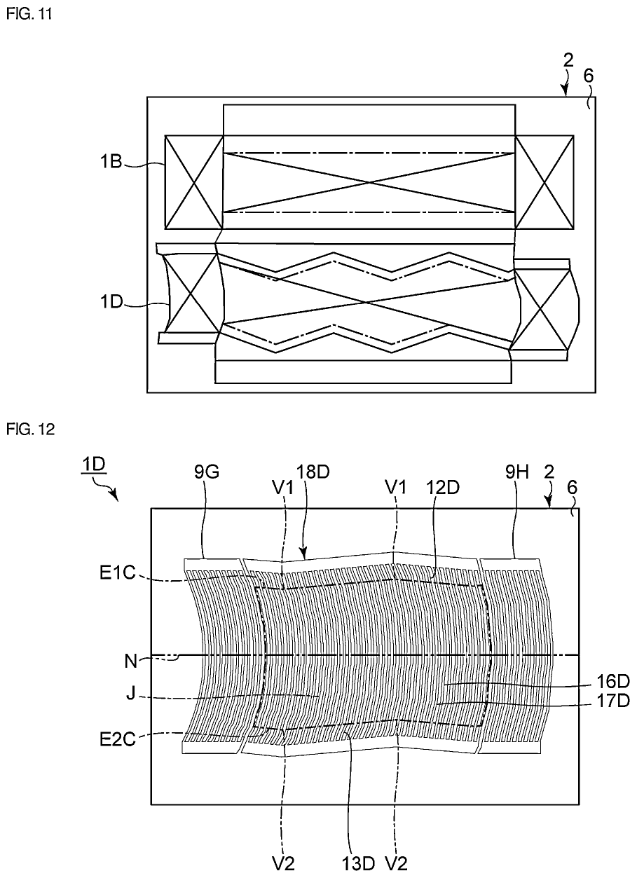

FIG. 11 is a schematic plan view of the acoustic wave device according to the second modified example of the first example embodiment. FIG. 12 is a schematic plan view of the first acoustic wave resonator in the second modified example of the first example embodiment. FIG. 12 schematically shows three segments.

As shown in FIG. 11, in a first acoustic wave resonator 1D, the shape of the plurality of electrode fingers in a plan view is not the curve shape. Specifically, as shown in FIG. 12, in the first IDT electrode 18D, the shape of the plurality of first electrode fingers 16D and the plurality of second electrode fingers 17D in a plan view is a shape curved in a plurality of nodes. More specifically, the shape of the plurality of first electrode fingers 16D and the plurality of second electrode fingers 17D in a plan view is a shape in which straight lines are connected in each of the nodes. In the present modified example, each electrode finger is curved as a whole to protrude in the right direction in FIG. 12. The shape of each electrode finger in a plan view can be approximated to the arc, the elliptical arc, or a parabola.

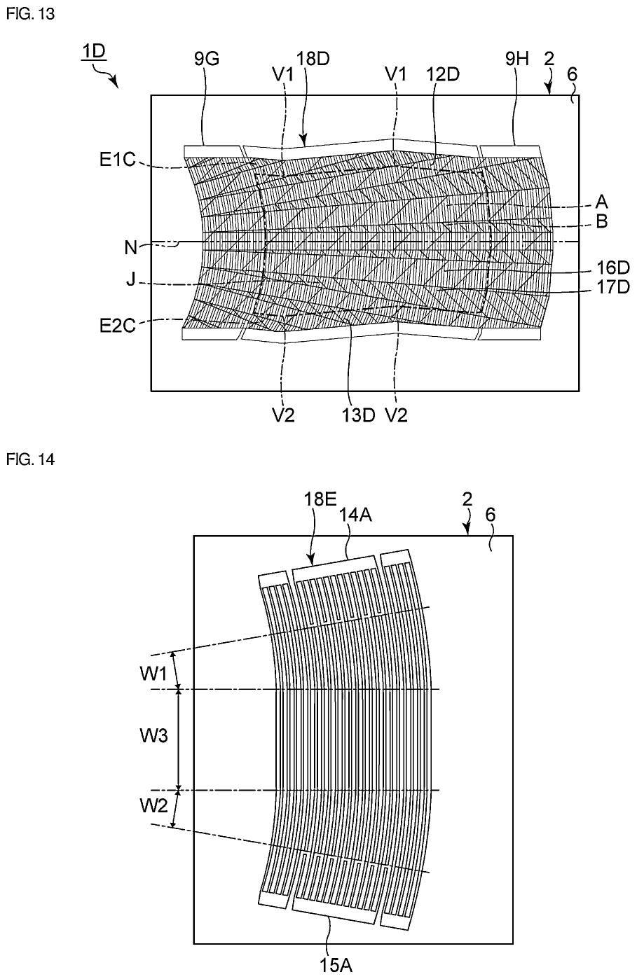

FIG. 13 is a schematic plan view showing a parallel region and a non-parallel region in the second modified example of the first example embodiment. In FIG. 13, each region is shown by hatching. The parallel region and a region obtained by extending the parallel region (to be described later) are provided with the same hatching. The non-parallel region and a region obtained by extending the non-parallel region (to be described later) are provided with the same hatching.

The intersection region J includes a plurality of parallel regions A and a plurality of non-parallel regions B. Specifically, the parallel region A is a region where the plurality of first electrode fingers 16D and the plurality of second electrode fingers 17D extend in parallel or substantially in parallel. In the present specification, description that the plurality of electrode fingers extend in parallel includes not only extending strictly in parallel but also extending in substantially parallel. Specifically, for example, even when an angle formed by the extending direction of one electrode finger and the extending direction of the other electrode finger is within a range of about ±1°, the electrode fingers extend in parallel. On the other hand, the non-parallel region B is a region where the extending directions of the plurality of first electrode fingers 16D and the plurality of second electrode fingers 17D intersect each other. The intersection region J may include at least two parallel regions A and at least one non-parallel region B.

In the first IDT electrode 18D, each of some of the plurality of parallel regions A and some of the plurality of non-parallel regions B includes a portion of all of the first electrode fingers 16D and all of the second electrode fingers 17D. The other parallel regions A include some of the plurality of first electrode fingers 16D and some of the plurality of second electrode fingers 17D. The parallel region A does not include the remaining plurality of electrode fingers. The same applies to the other non-parallel regions B. However, each of all of the parallel regions A and all of the non-parallel regions B may include a portion of all of the electrode fingers.

The parallel region A and the non-parallel region B are alternately disposed. Each of the plurality of first electrode fingers 16D and the second electrode fingers 17D linearly extends in the plurality of parallel regions A and the non-parallel regions B, and is curved at a boundary between the parallel region A and the non-parallel region B.

In the plurality of parallel regions A, the extending directions of the plurality of electrode fingers are different from each other. Therefore, in the intersection region J, the excitation direction and the excitation angle θ_{C_prop} of the acoustic wave are not uniform.

As in each of the electrode fingers of the first IDT electrode 18D, the shape of the plurality of reflector electrode fingers of the reflector 9G and the reflector 9H in a plan view is a shape curved in a plurality of nodes. Specifically, the plurality of reflector electrode fingers linearly extend in a region obtained by extending the parallel region A and a region obtained by extending the non-parallel region B. The plurality of reflector electrode fingers are curved at a boundary between the region obtained by extending the parallel region A and the region obtained by extending the non-parallel region B. In this manner, resonance characteristics can be more reliably improved.

In the present modified example, the shape of some of the plurality of first offset electrodes 12D and some of the plurality of second offset electrodes 13D in a plan view is a curve shape in which straight lines are connected to each other. The shape of the remaining offset electrode in a plan view is linear. The shape of all of the first offset electrodes 12D and all of the second offset electrodes 13D in a plan view may be the curve shape or linear.

FIG. 14 is a schematic plan view of the first acoustic wave resonator in the third modified example of the first example embodiment.

In the present modified example, the plurality of electrode fingers of the first IDT electrode 18E include a linear portion. Specifically, the intersection region of the first IDT electrode 18E includes a first region W1, a second region W2, and a third region W3. The first region W1, the second region W2, and the third region W3 are aligned in a direction in which the first busbar 14A and the second busbar 15A face each other. More specifically, the first region W1 and the second region W2 face each other with the third region W3 interposed therebetween. The first region W1 is located on the first busbar 14A side. The second region W2 is located on the second busbar 15A side. In the third region W3, the shape of the plurality of electrode fingers in a plan view is a linear shape. In the intersection region, the excitation direction and the excitation angle θ_{C_prop} of the acoustic wave are not uniform.

On the other hand, in the first region W1 and the second region W2, the shape of the plurality of electrode fingers in a plan view is the elliptical arc shape. In this way, each electrode finger includes a portion in which the curvature of the shape in a plan view is different. In the first region W1 and the second region W2, the shape of the plurality of electrode fingers in a plan view may be the arc shape. Alternatively, in the first region W1 and the second region W2, the shape of the plurality of electrode fingers in a plan view may be a curve shape that can be approximated to the arc or the elliptical arc.

In the present modified example, in all of the third regions W3, the extending direction of the propagation axis of the piezoelectric body layer 6 and the extending direction of the plurality of electrode fingers are orthogonal to each other. In the third region W3, the excitation angle θ_{C_prop} is about 0°. Therefore, the third region W3 is a stable region with respect to the propagation axis. Since the intersection region includes the third region W3, deterioration of a specific band can be reduced or prevented. The specific band is represented by |fr−fa|/fr×100 [%] when the resonant frequency is defined as fr and the anti-resonant frequency is defined as fa. The excitation angle θθₚᵣₒₚ in the third region W3 is not limited to about 0°.

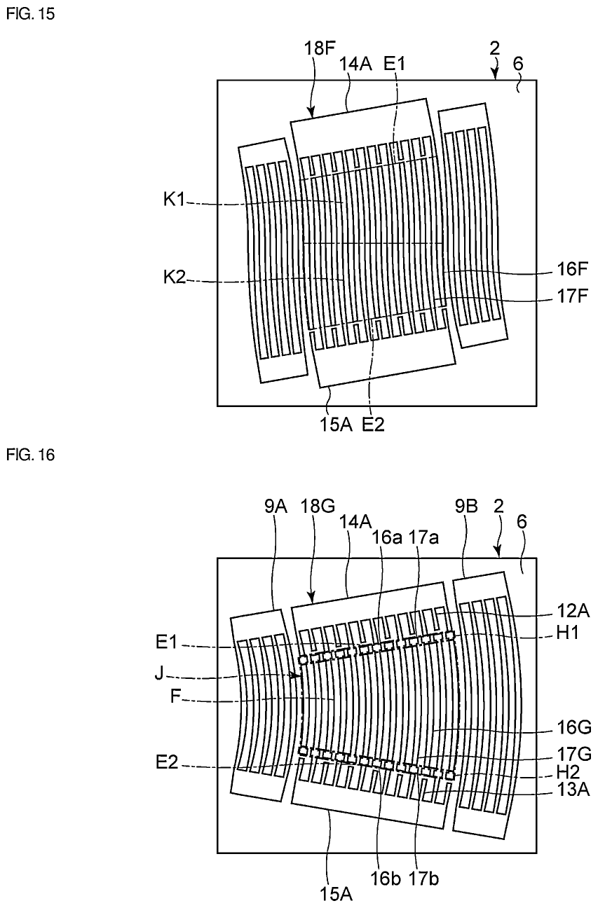

FIG. 15 is a schematic plan view of the first acoustic wave resonator in the fourth modified example of the first example embodiment.

In the first acoustic wave resonator of the present modified example, the intersection region includes a plurality of curve regions. Specifically, the plurality of curve regions include a first curve region K1 and a second curve region K2. The first curve region K1 includes the first envelope curve E1. The second curve region K2 includes the second envelope curve E2. A boundary between the first curve region K1 and the second curve region K2 is linear.

In the present modified example, in each curve region, each shape of the plurality of first electrode fingers 16F and the plurality of second electrode fingers 17F in a plan view is a single arc shape. Each shape of the plurality of electrode fingers in a plan view is a shape obtained by connecting two arcs to each other. In each electrode finger, two curve shapes are inverted with respect to each other at a boundary between the first curve region K1 and the second curve region K2.

Specifically, in the first curve region K1, the plurality of electrode fingers are curved to protrude in the right direction in FIG. 15. Each arc in the shape of a portion located in the first curve region K1 in the plurality of electrode fingers is the arc in a plurality of concentric circles. Therefore, the centers of the circles including the arcs in the shapes of the plurality of electrode fingers coincide or substantially coincide with each other in the first curve region K1.

On the other hand, in the second curve region K2, the plurality of electrode fingers are curved to protrude in the left direction in FIG. 15. Each arc in the shape of a portion located in the second curve region K2 in the plurality of electrode fingers is the arc in a plurality of concentric circles. Therefore, the centers of the circles including the arcs in the shapes of the plurality of electrode fingers coincide or substantially coincide with each other in the second curve region K2.

The center of the circle including the arc in the shape of the plurality of electrode fingers in the first curve region K1 and the center of the circle including the arc in the shape of the plurality of electrode fingers in the second curve region K2 face each other with the first IDT electrode 18F interposed therebetween.

In this way, each shape of the plurality of first electrode fingers 16F and the plurality of second electrode fingers 17F in a plan view may include at least two different curve shape portions in which curved directions of the first electrode finger 16F and the second electrode finger 17F are different from each other in the intersection region. In this case, in the intersection region, the excitation direction and the excitation angle θ_{C_prop} of the acoustic waves are not uniform.

In each curve region, the shape of the plurality of electrode fingers in a plan view may be a single elliptical arc. Alternatively, in each curve region, the shape of the plurality of electrode fingers in a plan view may be a curve shape that can be approximated to the single arc or the elliptical arc.

As in the plurality of electrode fingers of the first IDT electrode 18F, each shape of the plurality of reflector electrode fingers of each reflector in a plan view is a shape in which two arcs are connected. Each shape of the reflector electrode fingers in a plan view may be a shape obtained by connecting two elliptical arcs to each other. Alternatively, each shape of the reflector electrode fingers in a plan view may be a shape in which two curves that can be approximated to the arc or the elliptical arc are connected.

In the present modified example, both of the first envelope curve E1 and the second envelope curve are linear, and the first envelope curve E1 and the second envelope curve E2 extend in parallel or substantially in parallel. The first envelope curve E1 and the second envelope curve E2 extend inclined with respect to the propagation axis of the piezoelectric body layer 6.

FIG. 16 is a schematic plan view of the first acoustic wave resonator in the fifth modified example of the first example embodiment.

The intersection region J of the first IDT electrode 18G includes a central region F and a pair of edge regions. Specifically, the pair of edge regions include a first edge region H1 and a second edge region H2. The first edge region H1 includes the first envelope curve E1 as an end edge portion. The second edge region H2 includes the second envelope curve E2 as an end edge portion. The first edge region H1 and the second edge region H2 face each other with the central region F interposed therebetween. Each of the intersection regions of other example embodiments and modified examples also includes the first edge region, the second edge region, and the central region.

The first edge region H1 is a region where the tip portion of the second electrode finger 17G and the adjacent portion of the first electrode finger 16G are located. That is, the first edge region H1 is a region in a range of, for example, about 1λ along the extending direction of the electrode finger from the tip of the second electrode finger 17G when the second electrode finger 17G is set as a reference. Similarly, the second edge region H2 is a region in a range of about 1λ along the extending direction of the electrode finger from the tip of the first electrode finger 16G when the first electrode finger 16G is set as a reference.

Each electrode finger of the first IDT electrode 18G includes a wide portion in the first edge region H1 and the second edge region H2. The width of the electrode finger in the wide portion is wider than the width of the electrode finger in the central region F.

Specifically, the first electrode finger 16G includes a wide portion 16a in the first edge region H1. The second electrode finger 17G also includes a wide portion 17a in the first edge region H1. On the other hand, the first electrode finger 16G includes a wide portion 16b in the second edge region H2. The second electrode finger 17G also includes a wide portion 17b in the second edge region H2. In this manner, the acoustic velocity in the first edge region H1 and the second edge region H2 is lower than the acoustic velocity in the central region F. In this manner, a low acoustic velocity region is provided in the first edge region H1 and the second edge region H2. The low acoustic velocity region is a region whose acoustic velocity is lower than the acoustic velocity in the central region F.

In the present modified example, the central region F and the pair of low acoustic velocity regions are disposed in this order from the inner side portion to the outer side portion in the direction in which the first busbar 14A and the second busbar 15A face each other. In this manner, a piston mode is obtained. In this manner, a transverse mode can be reduced or prevented. In addition, energy of a main mode can be effectively confined on the central side portion of the intersection region J, and characteristics of the main mode can be improved.

The configuration of the first IDT electrode 18G is the same or substantially the same as that of the first example embodiment except for the first edge region H1 and the second edge region H2. Therefore, in the intersection region J, the excitation direction and the excitation angle θ_{C_prop} of the acoustic wave are not uniform.

In at least one of the first edge region H1 and the second edge region H2, at least one electrode finger may include the wide portion. However, in at least one of the first edge region H1 and the second edge region H2, it is preferable that the plurality of electrode fingers include the wide portion, and it is more preferable that all of the electrode fingers include the wide portion. In both of the first edge region H1 and the second edge region H2, it is more preferable that the plurality of electrode fingers include the wide portion, and it is even more preferable that all of the electrode fingers include the wide portion. In this manner, the piston mode can be more reliably obtained.

The shape of the plurality of electrode fingers of the first IDT electrode 18G in a plan view is the arc shape. However, a configuration in which the low acoustic velocity region is provided in the first edge region H1 or the second edge region H2 in the acoustic wave resonator can also be used for another configuration in which the shape of the electrode finger is different from that of the present modified example.

In the first IDT electrode 18G, the width of each electrode finger is wide over the entire or substantially the entire edge region. The shape of each wide portion in a plan view is a quadrangle. However, the width of each electrode finger may be wide in at least a portion of each edge region. The shape of each wide portion in a plan view is not limited to the quadrangle. For example, the width of each reflector electrode finger of each reflector may be wide in a portion located on an extension line of the first edge region H1 and a portion located on an extension line of the second edge region H2.

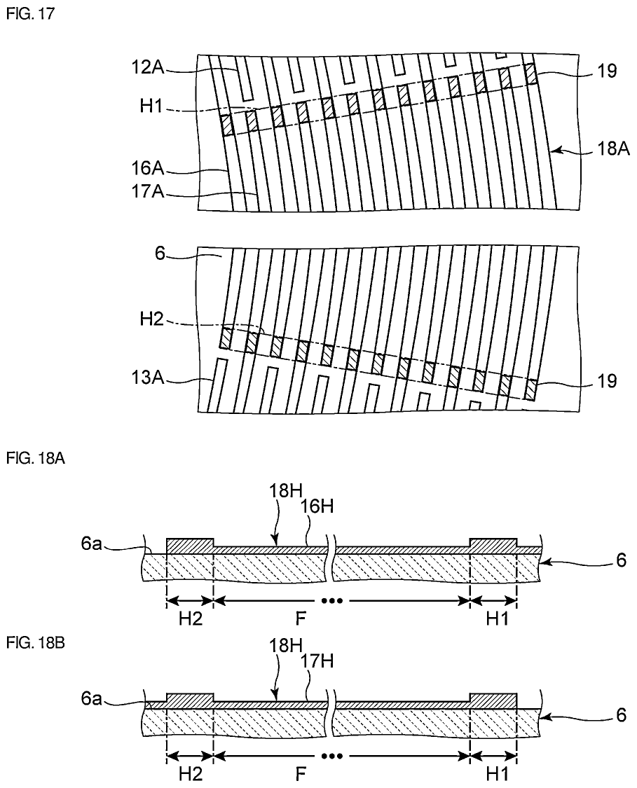

On the other hand, in the sixth modified example shown in FIG. 17, the plurality of mass addition films 19 are provided. In this manner, the low acoustic velocity region is provided in the first edge region H1 and the second edge region H2. Specifically, in the first edge region H1, the mass addition film 19 is provided on each of the first electrode fingers 16A and on each of the second electrode fingers 17A. The same applies to the second edge region H2. The configuration of the first IDT electrode 18A is the same or substantially the same configuration as that of the first example embodiment.

In the present modified example, each of the mass addition films 19 is provided only on one electrode finger. In this case, as a material of the mass addition film 19, appropriate metal or dielectric can be used. However, the mass addition film 19 may be provided over a plurality of electrode fingers. In this case, as the material of the mass addition film 19, appropriate dielectric can be used.

The mass addition film 19 may be laminated with at least one electrode finger in the plurality of electrode fingers in at least one of the first edge region H1 and the second edge region H2. Specifically, in at least one of the first edge region H1 and the second edge region H2, the mass addition film 19 may be provided to overlap at least one of the plurality of first electrode fingers 16A and the plurality of second electrode fingers 17A when viewed in a plan view. In this case, the low acoustic velocity region is provided in at least a portion of at least one of the first edge region H1 and the second edge region H2.

It is preferable that the plurality of electrode fingers are laminated with the mass addition film 19 in at least one of the first edge region H1 and the second edge region H2, and it is more preferable that all of the electrode fingers are laminated with the mass addition film 19. Alternatively, it is more preferable that the plurality of electrode fingers are laminated with the mass addition film 19 in both of the first edge region H1 and the second edge region H2. In this manner, the piston mode can be more reliably obtained. It is even more preferable that all of the electrode fingers are laminated with the mass addition film 19 in both edge regions. In this case, the low acoustic velocity region is provided in all of both edge regions. In this manner, the piston mode can be more reliably obtained.

In a portion where the electrode finger and the mass addition film 19 are laminated, the piezoelectric substrate 2, the electrode finger, and the mass addition film 19 are laminated in this order. However, in the portion where the electrode finger and the mass addition film 19 are laminated, the piezoelectric substrate 2, the mass addition film 19, and the electrode finger may be laminated in this order. That is, the mass addition film 19 may be provided between the piezoelectric substrate 2 and the electrode finger. A portion located on the extension line of the first edge region H1 and a portion located on the extension line of the second edge region H2 in each reflector electrode finger of each reflector may also be laminated with the mass addition film 19.

As a material of the mass addition film 19, for example, the same metal as the metal used for each electrode finger may be used. This configuration corresponds to the configuration of the seventh modified example shown in FIGS. 18A and 18B. That is, as shown in FIG. 18A, in the first IDT electrode 18H, the thickness of the first electrode finger 16H in the first edge region H1 and the second edge region H2 is thicker than the thickness of the first electrode finger 16H in the central region F. As shown in FIG. 18B, the thickness of the second electrode finger 17H in the first edge region H1 and the second edge region H2 is thicker than the thickness of the second electrode finger 17H in the central region F. In this manner, the low acoustic velocity region is provided in each of the first edge region H1 and the second edge region H2.

FIG. 18A schematically shows a cross section of the first electrode finger 16H along the extending direction of the first electrode finger 16H. Similarly, FIG. 18B schematically shows a cross section of the second electrode finger 17H along the extending direction of the second electrode finger 17H. The configuration of the first IDT electrode 18H is the same or substantially the same as that of the first example embodiment except for the first edge region H1 and the second edge region H2.

The thickness of at least one electrode finger in at least one of the first edge region H1 and the second edge region H2 may be thicker than the thickness of the electrode finger in the central region F. However, it is preferable that each thickness of the plurality of electrode fingers in at least one of the first edge region H1 and the second edge region H2 is thicker than the thickness of the electrode finger in the central region F. It is more preferable that each thickness of all of the electrode fingers in at least one of the first edge region H1 and the second edge region H2 is thicker than the thickness of the electrode finger in the central region F.

It is more preferable that each thickness of the plurality of electrode fingers in both of the first edge region H1 and the second edge region H2 is thicker than the thickness of the electrode finger in the central region F. It is even more preferable that each thickness of all of the electrode fingers in both of the first edge region H1 and the second edge region H2 is thicker than the thickness of the electrode finger in the central region F. In this manner, the piston mode can be more reliably obtained.

In the present modified example, the thickness of each electrode finger is thick over the entire or substantially the entire edge region. However, each electrode finger may be thick in at least a portion of each edge region. Each reflector electrode finger of each reflector may also be thick in a portion located on the extension line of the first edge region H1 and a portion located on the extension line of the second edge region H2. The low acoustic velocity region may be provided by at least one configuration of the fifth to seventh modified examples. For example, the low acoustic velocity region may be provided by a plurality of configurations in the fifth to seventh modified examples.

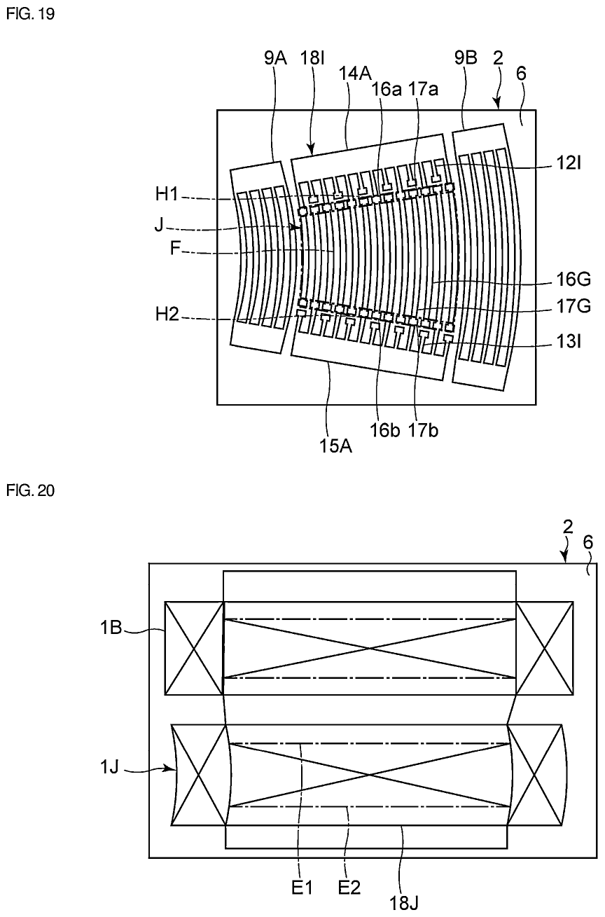

FIG. 19 is a schematic plan view of the first acoustic wave resonator in the eighth modified example of the first example embodiment.

The configuration of the first IDT electrode 18I in the present modified example is the same or substantially the same as the configuration of the first IDT electrode 18G in the fifth modified example, except for the first offset electrode 121 and the second offset electrode 131. Therefore, in the intersection region J, the excitation direction and the excitation angle θ_{C_prop} of the acoustic wave are not uniform. The width of the tip portion in the first offset electrode 121 of the present modified example is wider than the width of other portions in the first offset electrode 121. The width of the tip portion in the second offset electrode 131 is wider than the width of other portion in the second offset electrode 131.

FIG. 20 is a schematic plan view of the acoustic wave device in the ninth modified example of the first example embodiment.

In a first IDT electrode 18J of a first acoustic wave resonator 1J, the first envelope curve E1 and the second envelope curve E2 extend parallel or substantially parallel to the extending direction of the propagation axis of the piezoelectric body layer 6. As in the first example embodiment, the shape of the first IDT electrode 18J in a plan view is the arc shape. Therefore, in the intersection region, the excitation direction and the excitation angle θ_{C_prop} of the acoustic wave are not uniform.

The extending direction of the first envelope curve E1 may be parallel or substantially parallel to the extending direction of the second envelope curve E2, and may intersect the extending direction of the propagation axis.

The shape of the plurality of electrode fingers in a plan view may be the elliptical arc shape. Alternatively, the shape of the plurality of electrode fingers in a plan view may be the curve shape that can be approximated to the arc or the elliptical arc, or may be the parabola shape that cannot be approximated to the arc and the elliptical arc. On the other hand, as in the second modified example, the shape of the plurality of electrode fingers in a plan view may be a shape curved in a plurality of nodes.

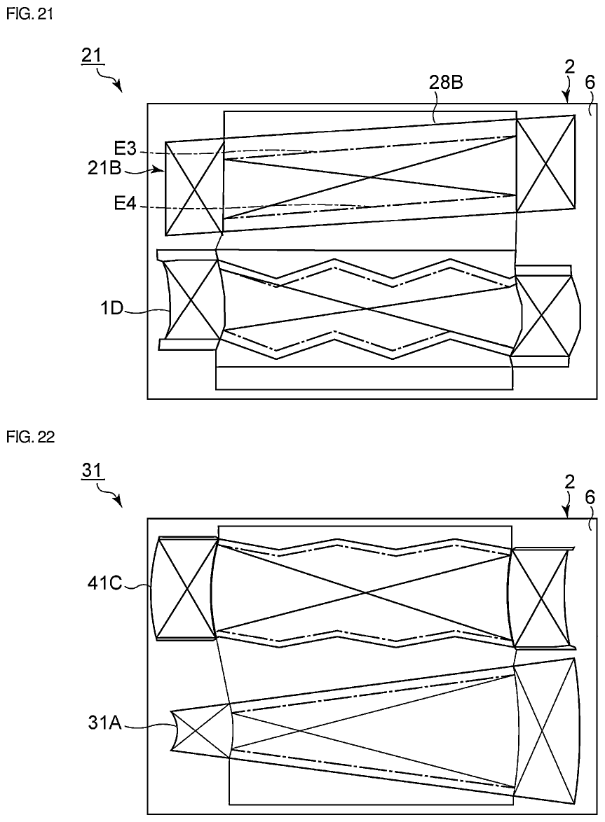

FIG. 21 is a schematic plan view of the acoustic wave device according to a second example embodiment of the present invention.

The present example embodiment is different from the first example embodiment in a configuration of a second acoustic wave resonator 21B. On the other hand, a first acoustic wave resonator 1D is provided as in the second modified example of the first example embodiment. Except for the above-described points, the acoustic wave device 21 of the present example embodiment has the same or substantially the same configuration as that of the first example embodiment. A second acoustic wave resonator 21B is the acoustic wave resonator that is not the excitation angle change resonator.

In the second acoustic wave resonator 21B, the third envelope curve E3 and the fourth envelope curve E4 of a second IDT electrode 28B extend inclined with respect to the propagation axis of the piezoelectric body layer 6. The third envelope curve E3 and the fourth envelope curve E4 are linear, and the third envelope curve E3 and the fourth envelope curve E4 extend in parallel or substantially in parallel. In this way, the second IDT electrode 28B is an inclined IDT electrode. The transverse mode can be reduced or prevented in the second acoustic wave resonator 21B.

Furthermore, as in the second modified example of the first example embodiment, the acoustic wave device 21 of the present example embodiment includes the first acoustic wave resonator 1D that is the excitation angle change resonator. Therefore, the unwanted waves outside the band can be reduced or prevented.

The first acoustic wave resonator 1D of the acoustic wave device 21 may have a configuration of the excitation angle change resonator, other than that of the second modified example of the first example embodiment.

FIG. 22 is a schematic plan view of the acoustic wave device according to a third example embodiment of the present invention.

The present example embodiment is different from the first example embodiment in that both of a first acoustic wave resonator 31A and a second acoustic wave resonator 41C are the excitation angle change resonators. Except for the above-described points, an acoustic wave device 31 of the present example embodiment has the same or substantially the same configuration as that of the acoustic wave device 1 of the first example embodiment.

The first acoustic wave resonator 31A has the same or substantially the same configuration as that of the first acoustic wave resonator 1A according to the first example embodiment. The second acoustic wave resonator 41C has the same or substantially the same configuration as that of the first acoustic wave resonator 1C in the first modified example of the first example embodiment. In the present example embodiment, the first acoustic wave resonator 31A and the second acoustic wave resonator 41C are the excitation angle change resonators, and are different from each other in the configuration in the intersection region.

In the first acoustic wave resonator 31A, the plurality of electrode fingers are curved to protrude in the right direction in FIG. 22. On the other hand, in the second acoustic wave resonator 41C, the plurality of electrode fingers are curved to protrude in the left direction in FIG. 22.

The phase characteristics are compared in the acoustic wave device 31 having the configuration of the present example embodiment and the acoustic wave device of the comparative example shown in FIG. 6. The results of the first example embodiment are shown together. The design parameters of the first example embodiment and the comparative example according to the comparison are the same or substantially the same as those of the first example embodiment and the comparative example according to the comparison shown in FIG. 7. The design parameters of the acoustic wave resonator having the configuration of the first acoustic wave resonator 31A in the present example embodiment are as follows.
Support Substrate: Material_Si, Surface Orientation_(111), ψ at Euler Angles (φ, θ, ψ) about 73°
First Layer of Intermediate Layer: Material_SiN, Thickness about 0.15λ
Second Layer of Intermediate Layer: Material_SiO₂, Thickness about 0.15λ
Piezoelectric Body Layer: Material_Rotational Y-cut 55° X-propagation LiTaO₃, Thickness about 0.2λ
First IDT Electrode: Material_Al, Thickness about 0.05λ
Dielectric Film: Material_SiO₂, Thickness about 0.015λ
Intersection Angle θ_{C1_AP}: about 5°
Intersection Angle θ_{C2_AP}: about −5°
Wavelength λ: about 2 μm in the portion where the Excitation
Angle θ_{C_prop} is about 0°
Number of Pairs of Electrode Fingers of First IDT Electrode: 80 pairs
Duty ratio: about 0.5 in the portion where the excitation angle θ_{C_prop} is about 0°, and the duty ratio decreases as the absolute value |θ_{C_prop}| of the excitation angle increases.
Gap Length: about 0.135λ
Length of Offset Electrode: about 3.5λ
Each Reflector: Number of Pairs of Reflector Electrode Fingers_20 Pairs

The design parameters of the acoustic wave resonator having the configuration of the second acoustic wave resonator 41C in the present example embodiment are as follows.
Support Substrate: Material_Si, Surface Orientation_(111), ψ at Euler Angles (φ, θ, ψ) about 73°
First Layer of Intermediate Layer: Material_SiN, Thickness about 0.15λ
Second Layer of Intermediate Layer: Material_SiO₂, Thickness about 0.15λ
Piezoelectric Body Layer: Material_Rotational Y-cut 55° X-propagation LiTaO₃, Thickness about 0.2λ
First IDT Electrode: Material_Al, Thickness about 0.05λ
Dielectric Film: Material_SiO₂, Thickness about 0.015λ
Wavelength λ: 2 μm in the portion where the Excitation Angle θ_{C_prop} is about 0°
Number of Pairs of Electrode Fingers of First IDT Electrode: 100 pairs
Duty Ratio: about 0.5 in the portion where the excitation angle θ_{C_prop} is about 0°
Gap Length: about 0.135λ
Length of Offset Electrode: about 3.5λ
Distance in Direction Orthogonal to Propagation Axis between
First Envelope Curve and Second Envelope Curve: about 25λ
First Envelope Curve: Absolute Value of Inclination Angle with respect to Propagation Axis about 20°, Number of Pairs of Electrode Fingers between Bending Portions_20 Pairs
Second Envelope Curve: Absolute Value of Inclination Angle with respect to Propagation Axis: about 20°, Number of Pairs of Electrode Fingers between Bending Portions: 20 pairs
Excitation Angle on First Envelope Curve: θ_{C_AP1_1}=about 12°, θ_{C_AP1_2}=about 8°, θ_{C_AP1_3}=about 16°, θ_{C_AP1_4}=about 10°, θ_{C_AP1_5}=about 16°, θ_{C_AP1_6}=about 9°
Excitation Angle on Second Envelope Curve: θ_{C_AP2_1}=about 9°, θ_{C_AP2_2}=about 15°, θ_{C_AP2_3}=about 8°, θ_{C_AP2_4}=about 15.5°, θ_{C_AP2_5}=about 10°, θ_{C_AP2_6}=about 16°
Each Reflector: Number of Pairs of Reflector Electrode Fingers_20 Pairs

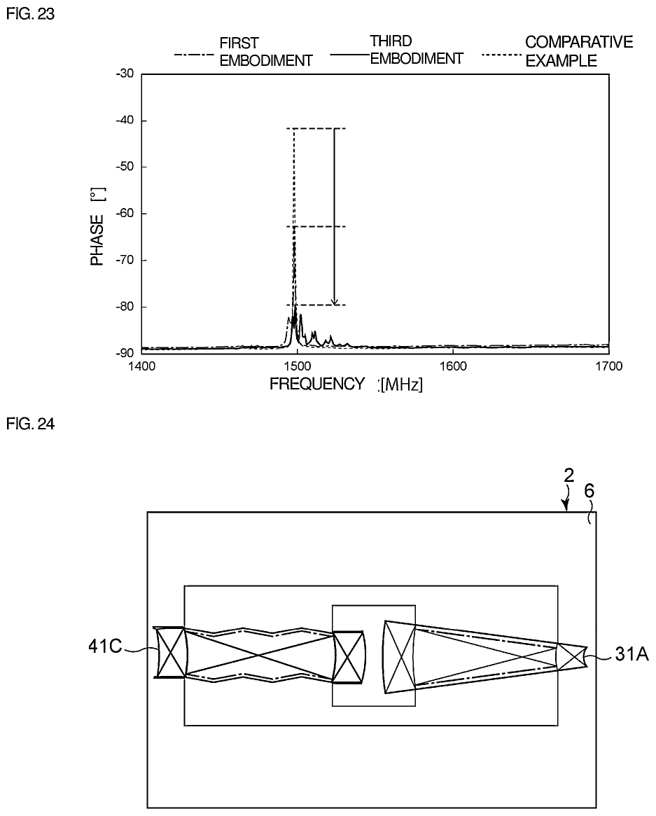

FIG. 23 is a view showing the phase characteristics in the vicinity of the frequency at which the unwanted waves are generated in the first example embodiment, the third example embodiment, and the comparative example.

As shown in FIG. 23, it can be understood that the Rayleigh waves as the unwanted waves can be further reduced or prevented in the first example embodiment, compared to the comparative example. Furthermore, it can be understood that the Rayleigh waves can be further reduced or prevented in the third example embodiment.

The reason is that in the third example embodiment, both of the first acoustic wave resonator 31A and the second acoustic wave resonator 41C are the excitation angle change resonators. In the acoustic wave device 31, the unwanted waves outside the band can be reduced or prevented in all of the acoustic wave resonators. In this manner, the unwanted waves outside the band can be further reduced or prevented as a whole in the acoustic wave device 31. In addition, the transverse mode can be reduced or prevented in both of the first acoustic wave resonator 31A and the second acoustic wave resonator 41C. Therefore, the transverse mode can also be effectively reduced or prevented as a whole in the acoustic wave device.

As described above, in the acoustic wave device, the acoustic wave resonators may be connected to each other in parallel. For example, in the first modified example of the third example embodiment shown in FIG. 24, the first acoustic wave resonator 31A and the second acoustic wave resonator 41C are connected to each other in parallel. In the present modified example, as in the third example embodiment, the unwanted waves outside the band can be reduced or prevented.

When the acoustic wave device includes the plurality of excitation angle change resonators, a combination of configurations of the excitation angle change resonators is not limited to a combination of the third example embodiment. Hereinafter, a second modified example and a third modified example of the third example embodiment, which are different from the third example embodiment only in a combination of the plurality of excitation angle change resonators, will be described. As in the third example embodiment, in the second modified example and the third modified example, the unwanted waves outside the band can be reduced or prevented.

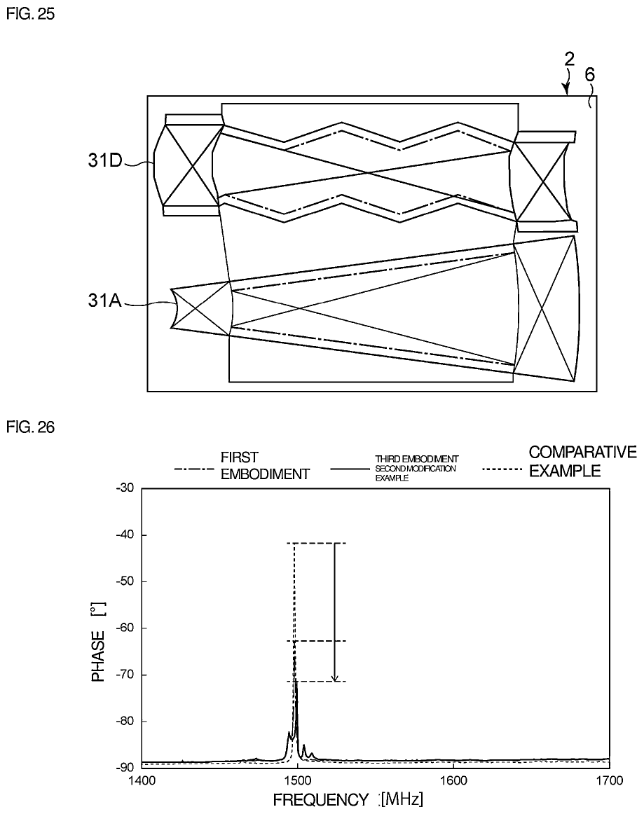

In the second modified example shown in FIG. 25, a second acoustic wave resonator 31D has the same or substantially the same configuration as that of the first acoustic wave resonator 1D in the second modified example of the first example embodiment. In the second acoustic wave resonator 31D, the plurality of electrode fingers are curved to protrude to the left side in FIG. 25. The first acoustic wave resonator 31A is formed in the same or substantially the same manner as that in the third example embodiment.

The phase characteristics are compared in the acoustic wave device having the configuration of the present modified example and the acoustic wave device of the comparative example shown in FIG. 6. The results of the first example embodiment are shown together. The design parameters of the first example embodiment and the comparative example according to the comparison are the same or substantially the same as those of the first example embodiment and the comparative example according to the comparison shown in FIG. 23. Furthermore, the design parameters of the acoustic wave resonator having the configuration of the first acoustic wave resonator 31A in the present modified example are the same or substantially the same as those of the third example embodiment according to the comparison shown in FIG. 23. The design parameters of the acoustic wave resonator having the configuration of the second acoustic wave resonator 31D in the present modified example are as follows.
Support Substrate: Material_Si, Surface Orientation_(111), ψ at Euler Angles (φ, θ, ψ) about 73°
First Layer of Intermediate Layer: Material_SiN, Thickness about 0.15λ
Second Layer of Intermediate Layer: Material_SiO₂, Thickness about 0.15λ
Piezoelectric Body Layer: Material_Rotational Y-cut 55° X-propagation LiTaO₃, Thickness about 0.2λ
First IDT Electrode: Material_Al, Thickness about 0.05λ
Dielectric Film: Material_SiO₂, Thickness about 0.015λ
Wavelength λ: about 2 μm in the portion where the Excitation
Angle θ_{C_prop} is about 0°
Number of Pairs of Electrode Fingers of First IDT Electrode: 100 pairs
Duty Ratio: about 0.5 in the portion where the excitation angle θ_{C_prop} is about 0°
Gap Length: about 0.135λ
Length of Offset Electrode: about 3.5λ
Distance in Direction Orthogonal to Propagation Axis between
First Envelope Curve and Second Envelope Curve: about 25λ
First Envelope Curve: Absolute Value of Inclination Angle with respect to Propagation Axis about 20°, Number of Pairs of Electrode Fingers between Bending Portions 20 Pairs
Second Envelope Curve: Absolute Value of Inclination Angle with respect to Propagation Axis: about 20°, Number of Pairs of Electrode Fingers between Bending Portions: 20 pairs
Excitation Angle on First Envelope Curve: θ_{C_AP1_1}=about 6.2°, θ_{C_AP1_2}=about 6.3°, θ_{C_AP1_3}=about 6.3°, θ_{C_AP1_4}=about 4.4°, θ_{C_AP1_5}=about 12°, θ_{C_AP1_6}=about 8.4°
Excitation Angle on Second Envelope Curve: θ_{C_AP2_1}=about 14.3°, θ_{C_AP2_2}=about 8.8°, θ_{C_AP2_3}=about 12.5°, θ_{C_AP2_4}=about 6°, θ_{C_AP2_5}=about 4.2°, θ_{C_AP2_6}=about 12.3°
Each Reflector: Number of Pairs of Reflector Electrode Fingers_20 Pairs

FIG. 26 is a view showing the phase characteristics in the vicinity of the frequency at which the unwanted waves are generated in the first example embodiment, the second modified example of the third example embodiment, and the comparative example.

As shown in FIG. 26, it can be understood that the Rayleigh waves, which are the unwanted waves outside the band, can be further reduced or prevented in the present modified example. Although not shown, in the present modified example, the transverse mode can be reduced or prevented in both of the first acoustic wave resonator 31A and the second acoustic wave resonator 31D. Therefore, the transverse mode can also be effectively reduced or prevented as a whole in the acoustic wave device.

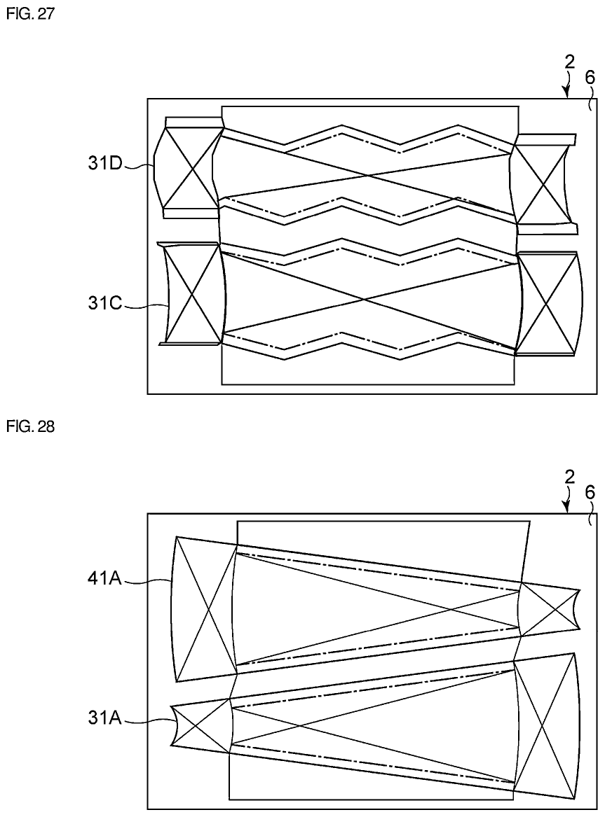

In the third modified example shown in FIG. 27, a first acoustic wave resonator 31C has the same or substantially the same configuration as that of the first acoustic wave resonator 1C in the first modified example of the first example embodiment. In the first acoustic wave resonator 31C, the plurality of electrode fingers are curved to protrude to the right side in FIG. 27. A second acoustic wave resonator 31D is provided in the same or substantially the same manner as that in the third modified example in the first example embodiment. In the second acoustic wave resonator 31D, the plurality of electrode fingers are curved to protrude to the left side in FIG. 27.

In the present modified example, in the first acoustic wave resonator 31C and the second acoustic wave resonator 31D which are all of the excitation angle change resonators, both of the first envelope curve and the second envelope curve include at least one bending portion. In this manner, the transverse mode can be effectively reduced or prevented as a whole in the acoustic wave device.

When the configurations of each example embodiment and each modified example are described, a plurality of examples of the excitation angle change resonator have been described. The examples of the configurations of the excitation angle change resonators in the intersection region can include first to third configurations below.

The first configuration is a configuration in the first example embodiment shown in FIG. 3 or in the description thereof. That is, in the configuration, the shape of the plurality of first electrode fingers and the plurality of second electrode fingers in a plan view includes the shape of the arc or the elliptical arc.

The second configuration is a configuration of the first modified example of the first example embodiment shown in FIG. 9. That is, in the configuration, the shape of the plurality of first electrode fingers and the plurality of second electrode fingers in a plan view is the curve shape, and each curvature of the first electrode finger and the second electrode finger is not constant. In the second configuration, in at least one set of electrode fingers in the plurality of first electrode fingers and the plurality of second electrode fingers, the curvatures are different from each other between the tip portions located on the first envelope curve side, between the adjacent portions, or between the tip portion and the adjacent portion.

The third configuration is a configuration of the second modified example of the first example embodiment shown in FIG. 12. That is, in the configuration, the intersection region includes the plurality of parallel regions where the plurality of first electrode fingers and the plurality of second electrode fingers extend in parallel, and a non-parallel region where the extending directions of the plurality of first electrode fingers and the plurality of second electrode fingers intersect each other. The third configuration is a configuration in which the parallel region and the non-parallel region are alternately disposed in at least a portion of the intersection region. Furthermore, the third configuration is a configuration in which each of the plurality of first electrode fingers and the plurality of second electrode fingers linearly extends in the plurality of parallel regions and the non-parallel regions, and is curved at the boundary between the parallel region and the non-parallel region.

It is preferable that the configuration of the intersection region of at least one of the excitation angle change resonators is one of the first to third configurations. In this manner, the unwanted waves outside the band can be more reliably reduced or prevented.

The first to third configurations refer to types of the configurations of the intersection region. For example, when the configurations of the intersection regions of both of the excitation angle change resonators are the same or substantially the same configuration in the first to third configurations, the configurations also include a case where parameters such as the duty ratio and the electrode finger pitch in both intersection regions are different from each other.

As in the first example embodiment or the second example embodiment, at least one of the plurality of acoustic wave resonators may be the acoustic wave resonator that is not the excitation angle change resonator. In this case, the configuration of the intersection region of the acoustic wave resonator may be any one configuration in the first to third configurations and the configuration in which the shape of the plurality of electrode fingers in a plan view is linear. However, in example embodiments of the present invention, at least one of the plurality of acoustic wave resonators is the excitation angle change resonator.

It is preferable that at least two of the plurality of acoustic wave resonators are the excitation angle change resonators, and the configurations in the intersection region of at least two of the excitation angle change resonators are any mutually different configuration in the first to third configurations. In this case, the shapes of the electrode fingers in a plan view are different from each other in at least two of the excitation angle change resonators. In this manner, the unwanted waves outside the band can be more reliably reduced or prevented as a whole in the acoustic wave device.

However, when the configurations are different from each other in the intersection regions of the plurality of excitation angle change resonators, the configuration of the intersection region of at least one of the excitation angle change resonators may be a configuration other than the first to third configurations, such as the third modified example of the first example embodiment shown in FIG. 14.

It is more preferable that all of the acoustic wave resonators in the acoustic wave device are the excitation angle change resonators, and the shapes of the electrode fingers are different from each other in all of the excitation angle change resonators. In this manner, the unwanted waves outside the band can be more reliably reduced or prevented.

In the excitation angle change resonator, the configuration of the first envelope curve and the second envelope curve may be any one of fourth to sixth configurations below. The fourth configuration is a configuration of the first modified example of the first example embodiment shown in FIG. 9. That is, in the configuration, both of the first envelope curve and the second envelope curve have shapes including at least one bending portion in which the extending direction is changed.

The fifth configuration is a configuration of the ninth modified example of the first example embodiment shown in FIG. 20. That is, in the configuration, both of the first envelope curve and the second envelope curve are linear, and the first envelope curve and the second envelope curve extend in parallel or substantially in parallel. In the fifth configuration, the extending direction of the first envelope curve and the second envelope curve may be parallel or substantially parallel to the extending direction of the propagation axis of the piezoelectric body layer 6, or may intersect the extending direction of the propagation axis.

The sixth configuration is a configuration of the first example embodiment shown in FIG. 3. That is, in the configuration, both of the first envelope curve and the second envelope curve are linear, and the extending direction of the first envelope curve extends and the extending direction of the second envelope curve intersect each other. The sixth configuration is not limited to the configuration in which the first envelope curve and the second envelope curve are line-symmetrically disposed. Specifically, for example, the absolute value of the angle formed by the first envelope curve and the extending direction of the propagation axis, and the absolute value of the angle formed by the second envelope curve and the extending direction of the propagation axis may be different from each other. The example includes a case where the absolute value of the intersection angle θ_{C1_AP} and the absolute value of the intersection angle θ_{C2_AP} are different from each other. More specifically, for example, the intersection angle θ_{C1_AP} may be about 10°, and the intersection angle θ_{C2_AP} may be about −5°. Alternatively, for example, the intersection angle θ_{C1_AP} may be about 10°, and the intersection angle θ_{C2_AP} may be about 0°.

At least two of the plurality of acoustic wave resonators may be the excitation angle change resonators, and the configurations of the first envelope curve and the second envelope curve in at least two of the excitation angle change resonators may be any mutually different configurations in the fourth to the sixth configurations.

FIG. 28 is a schematic plan view of the acoustic wave device according to a fourth example embodiment of the present invention.

The present example embodiment is different from the third example embodiment in that both of the first acoustic wave resonator 31A and the second acoustic wave resonator 41A have the same or substantially the same configuration as that of the first acoustic wave resonator 31A in the third example embodiment. In the second acoustic wave resonator 41A, the plurality of electrode fingers are curved to protrude to the left side in FIG. 28. Except for the above-described points, the acoustic wave device of the present example embodiment has the same or substantially the same configuration as that of the acoustic wave device 31 of the third example embodiment.

In the present example embodiment, as in the third example embodiment, the plurality of acoustic wave resonators of the acoustic wave device include the excitation angle change resonator. In this manner, the unwanted waves outside the band can be reduced or prevented.

The configuration of the intersection regions in both of the first acoustic wave resonator 31A and the second acoustic wave resonator 41A is the first configuration. Specifically, the shape of the plurality of electrode fingers in a plan view is the arc shape. However, the duty ratios are different from each other in the first acoustic wave resonator 31A and the second acoustic wave resonator 41A. Therefore, the shapes of the electrode fingers are different from each other in the intersection regions of the first acoustic wave resonator 31A and the second acoustic wave resonator 41A.

More specifically, for example, the duty ratio is about 0.626 in the portion where the excitation angle θ_{C_prop} is about 0° in the first acoustic wave resonator 31A. In the first acoustic wave resonator 31A, the duty ratio decreases as the absolute value |θ_{C_prop}| of the excitation angle increases.

On the other hand, for example, the duty ratio is about 0.5 in the portion where the excitation angle θ_{C_prop} is about 0° in the second acoustic wave resonator 41A. In the second acoustic wave resonator 41A, the duty ratio decreases as the absolute value |θ_{C_prop}| of the excitation angle increases.

In each of the first acoustic wave resonator 31A and the second acoustic wave resonator 41A, the duty ratio is changed in accordance with the excitation angle θ_{C_prop}. In this manner, the resonant frequencies or the anti-resonant frequencies substantially coincide with each other in all of the intersection regions. However, the duty ratio may be constant in all of the intersection regions. In this case, the parameter other than the duty ratio, such as the electrode finger pitch or the thickness of the electrode finger may be changed in accordance with the excitation angle θ_{C_prop} such that the resonant frequencies or the anti-resonant frequencies substantially coincide with each other in all of the intersection regions.

The plurality of acoustic wave resonators of the acoustic wave device may include a acoustic wave resonator other than the first acoustic wave resonator 31A and the second acoustic wave resonator 41A as the excitation angle change resonator. In this case as well, it is preferable that the duty ratios in the portion where the excitation angle θ_{C_prop} is about 0° are different from each other in at least two of the excitation angle change resonators. It is preferable that the duty ratio in least at the portion where the excitation angle θ_{C_prop} is about 0° is constant in each of at least two of the excitation angle change resonators. In this manner, as a whole in the acoustic wave device, the unwanted waves outside the band can be more reliably and effectively reduced or prevented.

In the present example embodiment, in the first acoustic wave resonator 31A and the second acoustic wave resonator 41A which are all the excitation angle change resonators, the configuration of both of the first envelope curve and the second envelope curve is the sixth configuration. Specifically, both of the first envelope curve and the second envelope curve are linear, the extending direction of the first envelope curve and the extending direction of the second envelope curve intersect each other, and the first envelope curve and the second envelope curve are line-symmetrically disposed with respect to the symmetry axis passing through the center of the intersection region. In this manner, the transverse mode can be effectively reduced or prevented as a whole in the acoustic wave device.

However, the configuration of the first envelope curve and the second envelope curve may be a configuration other than the sixth configuration. For example, in a modified example of the fourth example embodiment shown in FIG. 29, a first acoustic wave resonator 31J and a second acoustic wave resonator 41J have the same or substantially the same configuration as that of the first acoustic wave resonator 1J in the ninth modified example of the first example embodiment shown in FIG. 20. In the first acoustic wave resonator 31J, the plurality of electrode fingers are curved to protrude to the right side in FIG. 29. In the second acoustic wave resonator 41J, the plurality of electrode fingers are curved to protrude to the left side in FIG. 29.

In the present modified example, in the first acoustic wave resonator 31J and the second acoustic wave resonator 41J which are all the excitation angle change resonators, the configuration of the first envelope curve and the second envelope curve is the sixth configuration. Specifically, both of the first envelope curve and the second envelope curve are linear, and the first envelope curve and the second envelope curve extend in parallel or substantially in parallel.

The duty ratio of the first acoustic wave resonator 31J and the second acoustic wave resonator 41J is the same or substantially the same as that in the third example embodiment. More specifically, the duty ratio is about 0.626 in the portion where the excitation angle θ_{C_prop} is about 0° in the first acoustic wave resonator 31J. In the first acoustic wave resonator 31J, the duty ratio decreases as the absolute value |θ_{C_prop}| of the excitation angle increases.

On the other hand, the duty ratio is about 0.5 in the portion where the excitation angle θ_{C_prop} is about 0° in the second acoustic wave resonator 41J. In the second acoustic wave resonator 41J, the duty ratio decreases as the absolute value |θ_{C_prop}| of the excitation angle increases.

In the fourth example embodiment and the modified example thereof, whereas the configurations of the intersection region are the same or substantially the same in the excitation angle change resonators, the shapes of the electrode fingers are different from each other since the duty ratios are different from each other. However, the present invention is not limited thereto.

For example, the electrode finger pitches may be different from each other in at least two of the excitation angle change resonators. In this case, for example, in each of at least two of the excitation angle change resonators, the electrode finger pitch is constant in the portion where at least the excitation angle θ_{C_prop} is about 0°. The electrode finger pitches in the portion where the excitation angle θ_{C_prop} is about 0° are different from each other in at least two of the excitation angle change resonators.

The curvatures of the electrode fingers may be different from each other in at least two of the excitation angle change resonators. In this case, for example, in each of at least two of the excitation angle change resonators, the shape of the plurality of electrode fingers in a plan view is a curve shape. The curvatures are different from each other in at least one of the electrode fingers in an outermost direction and the electrode fingers in an innermost direction of at least two of the excitation angle change resonators.

As described above, the outer direction is a direction in which the curve shape portion of the electrode finger protrudes in the alignment direction of the plurality of electrode fingers. A direction opposite to the outer direction is an inner direction. More specifically, the inner direction is a direction in which the curve shape portion of the electrode finger is recessed in the alignment direction of the plurality of electrode fingers.

Alternatively, the ranges of the excitation angle θ_{C_prop} may be different from each other in at least two of the excitation angle change resonators. For example, maximum values of the excitation angle θ_{C_prop} in a positive direction may be different from each other in the two excitation angle change resonators. In both of these, the maximum values in a negative direction of the excitation angle θ_{C_prop} may be different from each other. Alternatively, in both of these, both of the positive maximum values and the negative maximum values of the excitation angle θ_{C_prop} may be different from each other.

For example, the configuration of the first envelope curve and the second envelope curve in both of the excitation angle change resonators is the sixth configuration, as in the first acoustic wave resonator 31A and the second acoustic wave resonator 41A shown in FIG. 28, and the ranges of the excitation angle θ_{C_prop} are different from each other. In this case, the absolute values of the intersection angle θ_{C1_AP} are different from each other in both of the excitation angle change resonators. Similarly, the absolute values of the intersection angle θ_{C2_AP} are also different from each other in both of these.

In the first to fourth example embodiments, an example in which the acoustic wave device includes two acoustic wave resonators as the plurality of acoustic wave resonators has been described. However, the acoustic wave device may include at least three of the acoustic wave resonators as the plurality of acoustic wave resonators. This example will be described below.

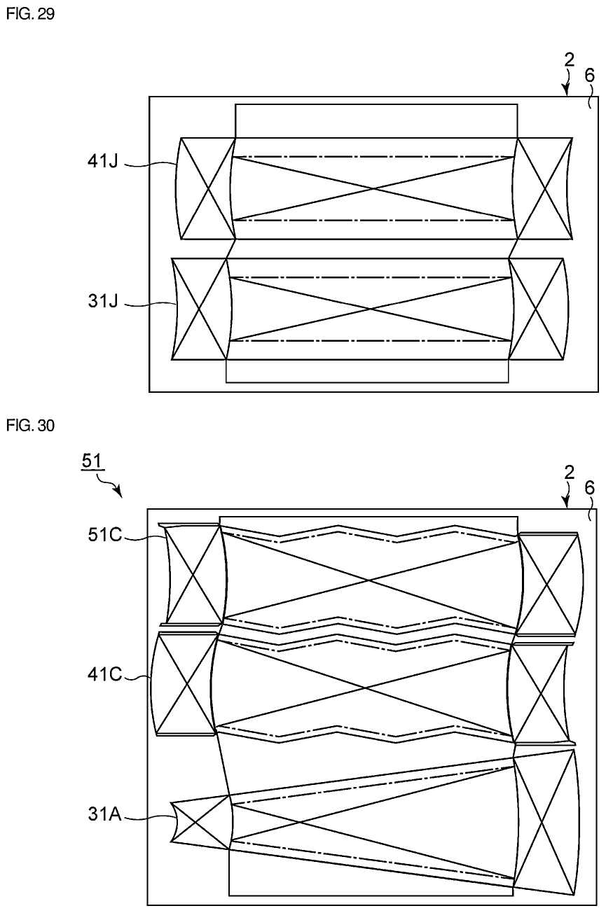

FIG. 30 is a schematic plan view of an acoustic wave device according to a fifth example embodiment of the present invention.

The present example embodiment is different from the third example embodiment in that an acoustic wave device 51 includes a third acoustic wave resonator 51C that is the excitation angle change resonator. Except for the above-described points, the acoustic wave device 51 of the present example embodiment has the same or substantially the same configuration as that of the acoustic wave device 31 of the third example embodiment. As in the third example embodiment, the acoustic wave device 51 includes the first acoustic wave resonator 31A and the second acoustic wave resonator 41C. The acoustic wave device 51 includes three excitation angle change resonators.

The first acoustic wave resonator 31A, the second acoustic wave resonator 41C, and the third acoustic wave resonator 51C are connected to each other in series in this order.

The third acoustic wave resonator 51C is structured in the same or substantially the same manner as that in the second acoustic wave resonator 41C. However, in the second acoustic wave resonator 41C and the third acoustic wave resonator 51C, the curvatures of the electrode finger and the curved directions of the electrode finger are different from each other. In the second acoustic wave resonator 41C, the plurality of electrode fingers are curved to protrude in the left direction in FIG. 30. On the other hand, in the third acoustic wave resonator 51C, the plurality of electrode fingers are curved to protrude in the right direction in FIG. 30.

The phase characteristics are compared in the acoustic wave device having the configuration of the present example embodiment and the acoustic wave device of the comparative example shown in FIG. 6. The results of the first example embodiment are shown together. The design parameters of the first example embodiment and the comparative example according to the comparison are the same or substantially the same as those of the first example embodiment and the comparative example according to the comparison shown in FIG. 23.

The design parameters of the acoustic wave resonator having the configuration of the first acoustic wave resonator 31A in the present example embodiment are the same or substantially the same as those in the third example embodiment according to the comparison shown in FIG. 23, except for the intersection angle.
Intersection Angle θ_{C1_AP} about 7.5°
Intersection Angle θ_{C2_AP} about −7.5°

The design parameters of the acoustic wave resonator having the configuration of the second acoustic wave resonator 41C in the present example embodiment are the same or substantially the same as those in the third example embodiment according to the comparison shown in FIG. 23, except for the excitation angle on the first envelope curve and the excitation angle on the second envelope curve.
Excitation Angle on First Envelope Curve: θ_{C_AP1_1}=about 13.5°, θ_{C_AP1_2}=about 9°, θ_{C_AP1_3}=about 16.5°, θ_{C_AP1_4}=about 9°, θ_{C_AP1_5}=about 16°, θ_{C_AP1_6}=about 9°
Excitation Angle on Second Envelope Curve: θ_{C_AP2_1}=about 10°, θ_{C_AP2_2}=about 16.5°, θ_{C_AP2_3}=about 10°, θ_{C_AP2_4}=about 17°, θ_{C_AP2_5}=about 9.5°, θ_{C_AP2_6}=about 16°

The design parameters of the acoustic wave resonator having the configuration of the third acoustic wave resonator 51C in the present example embodiment are the same or substantially the same as the design parameter of the acoustic wave resonator having the configuration of the second acoustic wave resonator 41C in the third example embodiment according to the comparison shown in FIG. 23.

FIG. 31 is a view showing the phase characteristics in the vicinity of the frequency at which the unwanted waves are generated in the first example embodiment, the fifth example embodiment, and the comparative example.

As shown in FIG. 31, it can be understood that the Rayleigh waves as the unwanted waves can be further reduced or prevented in the first example embodiment, compared to the comparative example. Furthermore, it can be understood that the Rayleigh waves can be further reduced or prevented in the fifth example embodiment. Although not shown, in the fifth example embodiment, the transverse mode can also be reduced or prevented in all of the first acoustic wave resonator 31A, the second acoustic wave resonator 41C, and the third acoustic wave resonator 51C. Therefore, the transverse mode can be effectively reduced or prevented as a whole in the acoustic wave device 51.

As in the fifth example embodiment, at least three of the plurality of acoustic wave resonators may be the excitation angle change resonators. It is preferable that the shapes of the electrode fingers in a plan view are different from each other in at least three of the excitation angle change resonators. In the fifth example embodiment, the configurations of the intersection regions are different between the first acoustic wave resonator 31A and the other acoustic wave resonator. Accordingly, the shapes of the electrode fingers in a plan view are different from each other. The curvatures of the electrode fingers are different from each other in the second acoustic wave resonator 41C and the third acoustic wave resonator 51C. Accordingly, the shapes of the electrode fingers in a plan view are different from each other. In this manner, the unwanted waves outside the band can be more reliably reduced or prevented as a whole in the acoustic wave device.

However, for example, in the second acoustic wave resonator 41C and the third acoustic wave resonator 51C, the shapes of the electrode fingers may be different from each other since the duty ratios are different from each other. This example is as follows. In the portion where the excitation angle θ_{C_prop} is about 0° in the second acoustic wave resonator 41C, the duty ratio is about 0.626. On the other hand, in the portion where the excitation angle θₚᵣₒₚ is about 0° in the third acoustic wave resonator 51C, the duty ratio is about 0.5.

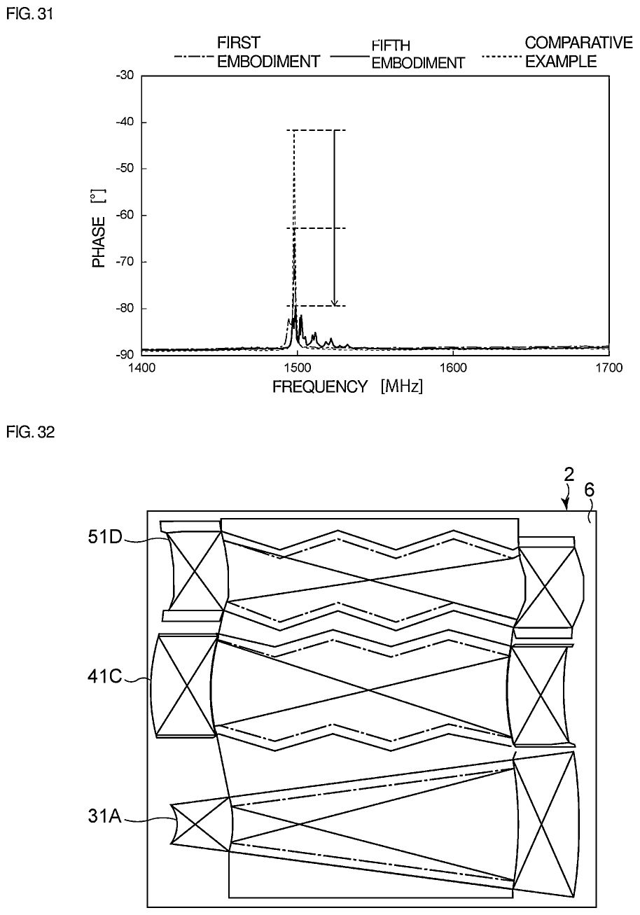

The configuration of the intersection region of the excitation angle change resonator in the acoustic wave device or the configuration of the first envelope curve and the second envelope curve is not particularly limited. For example, in a modified example of the fifth example embodiment shown in FIG. 32, the configuration of the intersection region of the third acoustic wave resonator 51D is the third configuration. That is, the shape of the plurality of electrode fingers of the third acoustic wave resonator 51D in a plan view is a shape curved in a plurality of nodes. In the present modified example, the first acoustic wave resonator 31A and the second acoustic wave resonator 41C are structured in the same or substantially the same manner as that in the fifth example embodiment.

In the present modified example, as in the fifth example embodiment, the unwanted waves outside the band and the transverse mode can be reduced or prevented.

The multilayer structure of the piezoelectric substrate is not limited to the configuration shown in FIG. 4. According to a sixth example embodiment of the present invention, an example in which the acoustic wave device includes the piezoelectric substrate different from that of the first example embodiment will be described.

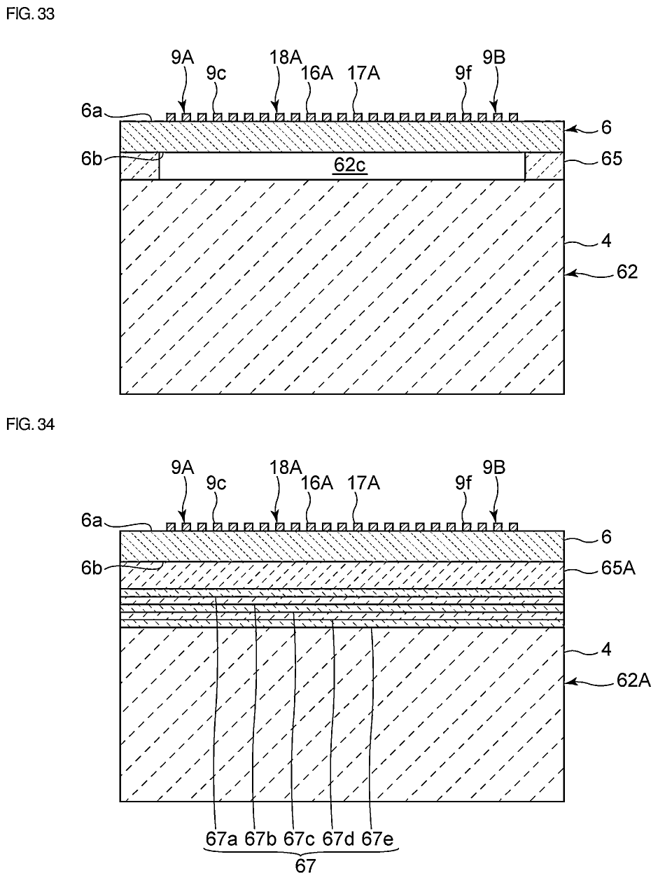

FIG. 33 is a schematic elevational cross-sectional view of the acoustic wave device according to the sixth example embodiment of the present invention.

The present example embodiment is different from the first example embodiment in a multilayer structure of a piezoelectric substrate 62. In FIG. 33, the first IDT electrode 18A is shown. However, although not shown, a second IDT electrode 18B the same or substantially the same as that of the first example embodiment is also provided on the piezoelectric substrate 62. Except for the above-described points, the acoustic wave device of the present example embodiment has the same or substantially the same configuration as that of the acoustic wave device 1 of the first example embodiment.

The piezoelectric substrate 62 includes the support substrate 4, an intermediate layer 65, and the piezoelectric body layer 6. The intermediate layer 65 is provided on the support substrate 4. The piezoelectric body layer 6 is provided on the intermediate layer 65. In the present example embodiment, the intermediate layer 65 has a frame shape. That is, the intermediate layer 65 includes a through-hole. The support substrate 4 closes one side of the through-hole of the intermediate layer 65. The piezoelectric body layer 6 closes the other side of the through-hole of the intermediate layer 65. In this manner, a hollow portion 62c is provided in the piezoelectric substrate 62. A portion of the piezoelectric body layer 6 and a portion of the support substrate 4 face each other with the hollow portion 62c interposed therebetween.

In the present example embodiment, the main mode can be reflected to the piezoelectric body layer 6 side. Therefore, energy of the acoustic wave can be effectively confined on the piezoelectric body layer 6 side. In addition, as in the first example embodiment, the unwanted waves outside the band can be reduced or prevented.

Hereinafter, a first modified example and a second modified example of the sixth example embodiment, which are different from the sixth example embodiment only in the multilayer structure of the piezoelectric substrate, will be described. As in the sixth example embodiment, in the first modified example and the second modified example, the unwanted waves outside the band can be reduced or prevented, and energy of the acoustic wave can be effectively confined on the piezoelectric body layer 6 side.

In the first modified example shown in FIG. 34, a piezoelectric substrate 62A includes the support substrate 4, an acoustic reflection film 67, an intermediate layer 65A, and the piezoelectric body layer 6. The acoustic reflection film 67 is provided on the support substrate 4. The intermediate layer 65A is provided on the acoustic reflection film 67. The piezoelectric body layer 6 is provided on the intermediate layer 65A. The intermediate layer 65A is the low acoustic velocity film.

The acoustic reflection film 67 is a multilayer body having a plurality of acoustic impedance layers. Specifically, the acoustic reflection film 67 includes a plurality of low acoustic impedance layers and a plurality of high acoustic impedance layers. The high acoustic impedance layer is a layer having a relatively high acoustic impedance. More specifically, the plurality of high acoustic impedance layers of the acoustic reflection film 67 are a high acoustic impedance layer 67a, a high acoustic impedance layer 67c, and a high acoustic impedance layer 67e. On the other hand, the low acoustic impedance layer is a layer having a relatively low acoustic impedance. More specifically, the plurality of low acoustic impedance layers of the acoustic reflection film 67 are a low acoustic impedance layer 67b and a low acoustic impedance layer 67d. The low acoustic impedance layer and the high acoustic impedance layer are alternately laminated. The high acoustic impedance layer 67a is a layer located closest to the piezoelectric body layer 6 side in the acoustic reflection film 67.

The acoustic reflection film 67 includes two low acoustic impedance layers and three high acoustic impedance layers. However, the acoustic reflection film 67 may include at least one low acoustic impedance layer and at least one high acoustic impedance layer.

As a material of the low acoustic impedance layer, for example, silicon oxide or aluminum can be used. As a material of the high acoustic impedance layer, for example, metal such as platinum or tungsten, or a dielectric such as aluminum nitride or silicon nitride can be used. The material of the intermediate layer 65A may be the same as the material of the low acoustic impedance layer.

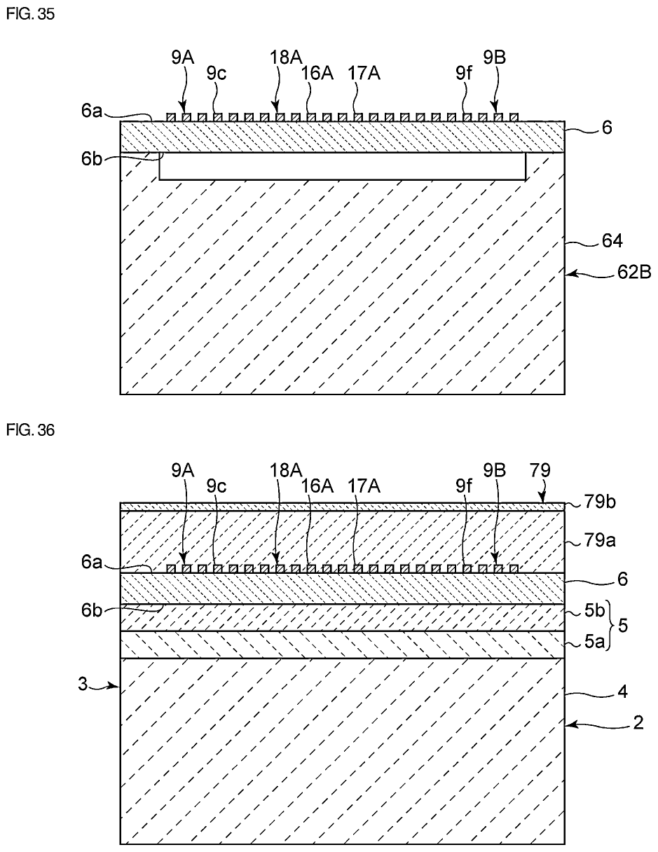

In the second modified example shown in FIG. 35, a piezoelectric substrate 62B includes a support substrate 64 and the piezoelectric body layer 6. The piezoelectric body layer 6 is directly provided on the support substrate 64. More specifically, the support substrate 64 includes a recessed portion. The piezoelectric body layer 6 is provided on the support substrate 64 to close the recessed portion. In this manner, a hollow portion is provided in the piezoelectric substrate 62B. The hollow portion overlaps at least a portion of the first IDT electrode 18A in a plan view.

FIG. 36 is a schematic elevational cross-sectional view of the acoustic wave device according to a seventh example embodiment of the present invention.

The present example embodiment is different from the first example embodiment in that the first IDT electrode 18A is embedded in a protection film 79. Although not shown, the present example embodiment is different from the first example embodiment in that the second IDT electrode 18B shown in FIG. 1 is embedded in the protection film 79. Except for the above-described points, the acoustic wave device of the present example embodiment has the same or substantially the same configuration as that of the acoustic wave device 1 of the first example embodiment.

Specifically, the protection film 79 is provided on the piezoelectric body layer 6 to cover the first IDT electrode 18A. The thickness of the protection film 79 is thicker than the thickness of the first IDT electrode 18A. The first IDT electrode 18A is embedded in the protection film 79. In this manner, the first IDT electrode 18A is less likely to be damaged. Similarly, the second IDT electrode 18B is also less likely to be damaged.

The protection film 79 includes a first protection layer 79a and a second protection layer 79b. The first IDT electrode 18A and the second IDT electrode 18B are embedded in the first protection layer 79a. The second protection layer 79b is provided on the first protection layer 79a. In this manner, a plurality of advantageous effects can be achieved by the protection film 79. Specifically, in the present example embodiment, for example, silicon oxide is used as the material of the first protection layer 79a. In this manner, the absolute value of a temperature coefficient of a frequency (TCF) in the acoustic wave device can be reduced. Therefore, temperature characteristics of the acoustic wave device can be improved. Silicon nitride, for example, is used for the second protection layer 79b. In this manner, humidity resistance of the acoustic wave device can be improved.

In addition, in the present example embodiment, the first IDT electrode 18A and the second IDT electrode 18B are structured and disposed in the same or substantially the same manner as that in the first example embodiment. In this manner, the unwanted waves outside the band can be reduced or prevented.

The material of the first protection layer 79a and the second protection layer 79b is not limited to the above-described example. The protection film 79 may include a single layer, or may include a multilayer body including three or more layers.

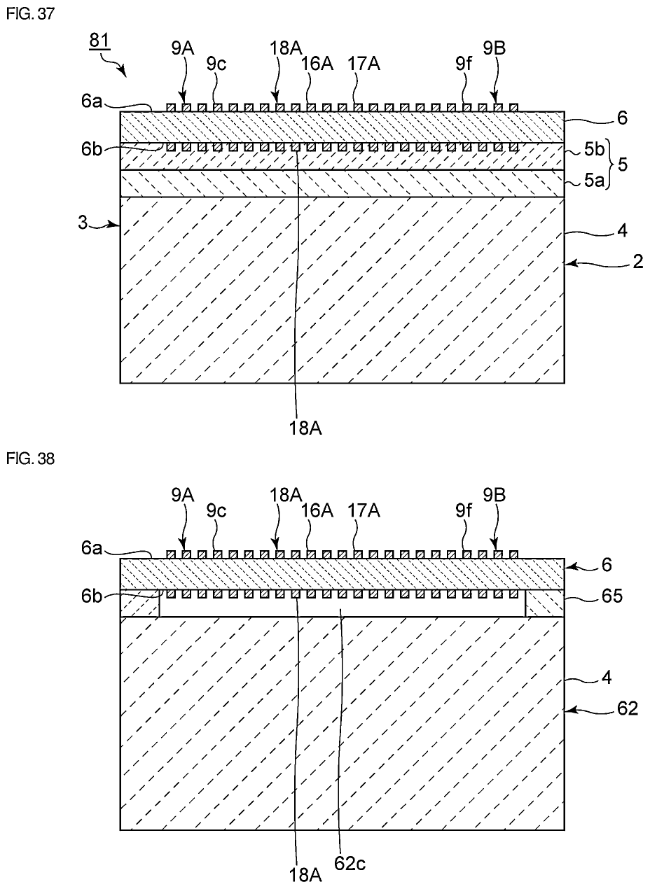

FIG. 37 is a schematic elevational cross-sectional view of the acoustic wave device according to an eighth example embodiment of the present invention.

The present example embodiment is different from the first example embodiment in that the first IDT electrode 18A is provided on both of the first main surface 6a and the second main surface 6b of the piezoelectric body layer 6. Although not shown, the present example embodiment is different from the first example embodiment in that the second IDT electrode 18B shown in FIG. 1 is provided on both of the first main surface 6a and the second main surface 6b of the piezoelectric body layer 6. The first IDT electrode 18A and the second IDT electrode 18B which are provided on the second main surface 6b are embedded in the second layer 5b in the intermediate layer 5. Except for the above-described points, the acoustic wave device 81 of the present example embodiment has the same configuration as that of the acoustic wave device 1 of the first example embodiment.

The first IDT electrode 18A provided on the first main surface 6a and the first IDT electrode 18A provided on the second main surface 6b of the piezoelectric body layer 6 face each other with the piezoelectric body layer 6 interposed therebetween. The second IDT electrode 18B provided on the first main surface 6a and the second IDT electrode 18B provided on the second main surface 6b of the piezoelectric body layer 6 face each other with the piezoelectric body layer 6 interposed therebetween.

In the acoustic wave device 81 of the present example embodiment, the first IDT electrode 18A and the second IDT electrode 18B are provided on the first main surface 6a in the same or substantially the same manner as that in the first example embodiment. The first IDT electrode 18A and the second IDT electrode 18B are connected to each other without using a functional electrode of the other acoustic wave resonator. The same applies to the second main surface 6b. In this manner, as in the first example embodiment, the unwanted waves outside the band can be reduced or prevented.

For example, in the first IDT electrode 18A provided on the first main surface 6a and the second main surface 6b of the piezoelectric body layer 6, the design parameters may be different from each other. For example, in the second IDT electrode 18B provided on the first main surface 6a and the second main surface 6b, the design parameters may be different from each other.

Hereinafter, first to third modified examples of the eighth example embodiment, which are different from the eighth example embodiment in at least one of the configuration of the electrode provided on the second main surface of the piezoelectric body layer and the multilayer structure of the piezoelectric substrate will be described. As in the eighth example embodiment, in the first to third modified examples, the unwanted waves outside the band can be reduced or prevented.

In the first modified example shown in FIG. 38, the piezoelectric substrate 62 is structured in the same or substantially the same manner as that in the sixth example embodiment. Specifically, the piezoelectric substrate 62 includes the support substrate 4, the intermediate layer 65, and the piezoelectric body layer 6. The first IDT electrode 18A provided on the second main surface 6b of the piezoelectric body layer 6 is located inside the hollow portion 62c. Although not shown, the second IDT electrode 18B provided on the second main surface 6b is also located inside the hollow portion 62c.

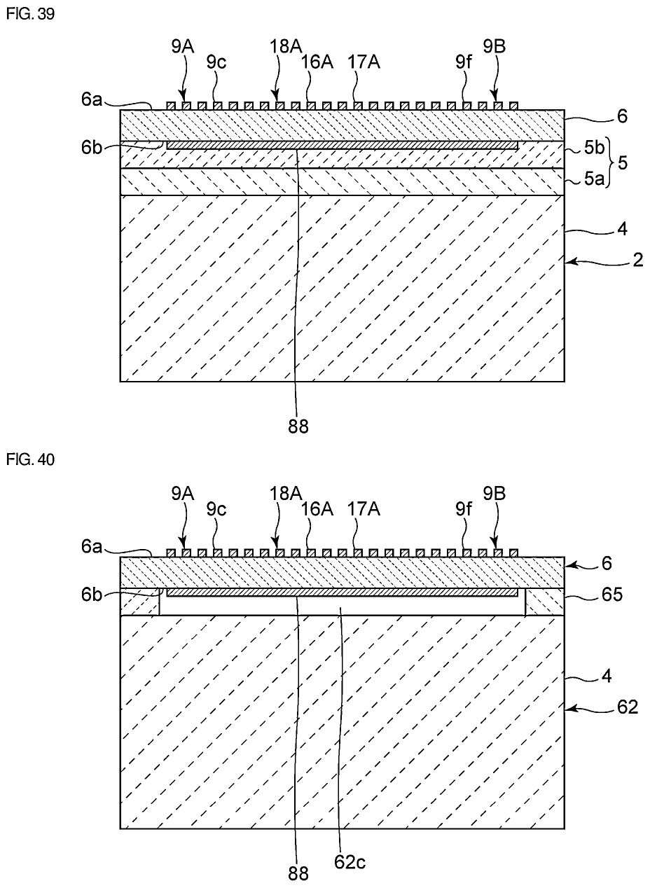

In the second modified example shown in FIG. 39, a plate-shaped electrode 88 is provided on the second main surface 6b of the piezoelectric body layer 6. The first IDT electrode 18A and the electrode 88 face each other with the piezoelectric body layer 6 interposed therebetween. Another electrode 88 is also provided on the second main surface 6b to face the second IDT electrode 18B. Each electrode 88 is embedded in the second layer 5b.

In the third modified example shown in FIG. 40, the piezoelectric substrate 62 is structured in the same or substantially the same manner as that in the first modified example, and the electrode 88 which is the same or substantially the same as that in the second modified example is provided on the second main surface 6b of the piezoelectric body layer 6. The electrode 88 is located inside the hollow portion 62c.

In the sixth to eighth example embodiments and each of the modified examples, examples in which the first IDT electrode and the second IDT electrode have the same or substantially the same configuration and disposition as those of the first example embodiment have been described. However, even when the configuration and the disposition of the plurality of IDT electrodes are the configuration and the disposition of an example embodiment of the present invention other than those in the first example embodiment, the piezoelectric substrate of the sixth to eighth example embodiments and each of the modified examples can be used.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a plurality of acoustic wave resonators each including a piezoelectric substrate including a piezoelectric body layer, and an interdigital transducer (IDT) electrode on the piezoelectric substrate and including a plurality of electrode fingers; wherein
at least one of the plurality of acoustic wave resonators is an excitation angle change resonator;
in the excitation angle change resonator, the piezoelectric body layer includes a propagation axis, and the plurality of electrode fingers are curved;
in the excitation angle change resonator, an excitation direction of an acoustic wave in a portion of an electrode finger of the plurality of electrode fingers is one of a first direction perpendicular or substantially perpendicular to an extending direction of the electrode finger, a second direction connecting a shortest distance between the electrode finger and an electrode finger of the plurality of adjacent to the electrode finger, and a third direction of an electric field vector generated between the electrode finger and the electrode finger adjacent to the electrode finger;
in the excitation angle change resonator, when an angle between the excitation direction and an extending direction of the propagation axis is defined as an excitation angle, the excitation angle is not uniform in the IDT electrode;
the plurality of acoustic wave resonators are connected to each other in series or in parallel;
other elements are not connected between the plurality of acoustic wave resonators; and
a circuit of the acoustic wave device is not branched between the plurality of acoustic wave resonators.

2. The acoustic wave device according to claim 1, wherein
at least two of the plurality of acoustic wave resonators are the excitation angle change resonators; and
shapes of the plurality of electrode fingers in a plan view are different from each other in the at least two of the excitation angle change resonators.

3. The acoustic wave device according to claim 2, wherein
the plurality of acoustic wave resonators include at least three acoustic wave resonators;
at least three of the plurality of acoustic wave resonators are the excitation angle change resonators; and
shapes of the plurality of electrode fingers in a plan view are different from each other in the at least three of the excitation angle change resonators.

4. The acoustic wave device according to claim 2, wherein
a duty ratio in a portion where at least the excitation angle is about 0° is constant in each of the at least two of the excitation angle change resonators; and
duty ratios in the portion where the excitation angle is about 0° are different from each other in the at least two of the excitation angle change resonators.

5. The acoustic wave device according to claim 2, wherein
an electrode finger pitch in a portion where at least the excitation angle is about 0° is constant in each of the at least two of the excitation angle change resonators; and
electrode finger pitches in the portion where the excitation angle is 0° are different from each other in the at least two of the excitation angle change resonators.

6. The acoustic wave device according to claim 2, wherein
in each of the at least two of the excitation angle change resonators, a shape of the plurality of electrode fingers in a plan view is curved; and
when a direction in which a portion with a curve shape of the electrode finger protrudes in an alignment direction of the plurality of electrode fingers is defined as an outer direction, and a direction in which the portion with the curve shape of the electrode finger is recessed in the alignment direction of the plurality of electrode fingers is defined as an inner direction, curvatures are different from each other in at least one of the electrode fingers located closest in the outer direction and the electrode fingers located closest in the inner direction in at least two of the excitation angle change resonators.

7. The acoustic wave device according to claim 2, wherein ranges of the excitation angle are different from each other in the at least two of the excitation angle change resonators.

8. The acoustic wave device according to claim 1, wherein
the plurality of electrode fingers in the IDT electrode of the excitation angle change resonator include a plurality of first electrode fingers and a plurality of second electrode fingers which are interdigitated with each other;
a virtual line connecting tips in tip portions of the plurality of second electrode fingers is defined as a first envelope curve;
a virtual line connecting tips in tip portions of the plurality of first electrode fingers is defined as a second envelope curve;
a region between the first envelope curve and the second envelope curve is an intersection region in the IDT electrode;
a portion including a portion located on the first envelope curve in the plurality of first electrode fingers and adjacent to the tip portion of one of the plurality of second electrode fingers is an adjacent portion of the plurality of first electrode fingers;
a portion including a portion located on the second envelope curve in the plurality of second electrode fingers and adjacent to the tip portion of one of the plurality of first electrode fingers is an adjacent portion of the plurality of second electrode fingers;
a configuration of the excitation angle change resonator in the intersection region is one of a first configuration in which a shape of the plurality of first electrode fingers and the plurality of second electrode fingers in a plan view includes a shape of an arc or an elliptical arc, a second configuration in which the shape of the plurality of first electrode fingers and the plurality of second electrode fingers in a plan view is a curve shape, a curvature is not constant in each of the plurality of first electrode fingers and the plurality of second electrode fingers, and curvatures are different from each other between the tip portions located on a first envelope curve side in at least one set of electrode fingers in the plurality of first electrode fingers and the plurality of second electrode fingers, between the adjacent portions or between the tip portion and the adjacent portion, and a third configuration in which in the intersection region, a plurality of parallel regions where the plurality of first electrode fingers and the plurality of second electrode fingers extend in parallel or substantially in parallel, and a non-parallel region where extending directions of the plurality of first electrode fingers and the plurality of second electrode fingers intersect each other are included, in at least a portion of the intersection region, the parallel region and the non-parallel region are alternately provided, and each of the plurality of first electrode fingers and the plurality of second electrode fingers linearly extends in the plurality of parallel regions and the non-parallel region, and is curved at a boundary between the parallel region and the non-parallel region.

9. The acoustic wave device according to claim 8, wherein
the excitation angle change resonator includes a pair of reflectors on the piezoelectric body layer and facing each other with the IDT electrode interposed therebetween, and each including a plurality of reflector electrode fingers;
a configuration of the excitation angle change resonator in the intersection region is one of the first configuration and the second configuration; and
a shape of the plurality of reflector electrode fingers in a plan view includes a curve shape.

10. The acoustic wave device according to claim 8, wherein
the excitation angle change resonator includes a pair of reflectors on the piezoelectric body layer and facing each other with the IDT electrode interposed therebetween, and each including a plurality of reflector electrode fingers;
a configuration of the excitation angle change resonator in the intersection region is the third configuration; and
a shape of the plurality of reflector electrode fingers in a plan view includes a shape curved in a plurality of nodes.

11. The acoustic wave device according to claim 8, wherein
at least two of the plurality of acoustic wave resonators are the excitation angle change resonators; and
configurations of the at least two of the excitation angle change resonators in the intersection region are any mutually different configurations in the first to third configurations.

12. The acoustic wave device according to claim 1, wherein
the plurality of electrode fingers in the IDT electrode of the excitation angle change resonator include a plurality of first electrode fingers and a plurality of second electrode fingers which are interdigitated with each other;
a virtual line connecting tips in tip portions of the plurality of second electrode fingers is defined as a first envelope curve;
a virtual line connecting tips in tip portions of the plurality of first electrode fingers is defined as a second envelope curve;
a region between the first envelope curve and the second envelope curve is an intersection region in the IDT electrode; and
when a configuration in which both of the first envelope curve and the second envelope curve have a shape including at least one bending portion whose extending direction is changed is defined as a fourth configuration, a configuration in which both of the first envelope curve and the second envelope curve are linear, and the first envelope curve and the second envelope curve extend in parallel or substantially in parallel is defined as a fifth configuration, and a configuration in which both of the first envelope curve and the second envelope curve are linear, and an extending direction of the first envelope curve and an extending direction of the second envelope curve intersect each other is defined as a sixth configuration, a configuration of the first envelope curve and the second envelope curve of at least one of the excitation angle change resonators is one configuration of the fourth to sixth configurations.

13. The acoustic wave device according to claim 12, wherein
at least two of the plurality of acoustic wave resonators are the excitation angle change resonators; and
configurations of the first envelope curves and the second envelope curves of the at least two of the excitation angle change resonators are any mutually different configurations in the fourth to sixth configurations.

14. The acoustic wave device according to claim 12, wherein the configuration of the first envelope curve and the second envelope curve is the fourth configuration in all of the excitation angle change resonators.

15. The acoustic wave device according to claim 12, wherein the configuration of the first envelope curve and the second envelope curve is the fifth configuration in all of the excitation angle change resonators.

16. The acoustic wave device according to claim 12, wherein the configuration of the first envelope curve and the second envelope curve is the sixth configuration in all of the excitation angle change resonators.

17. The acoustic wave device according to claim 1, wherein
all of the plurality of acoustic wave resonators are the excitation angle change resonators; and
shapes of the plurality of electrode fingers in a plan view are different from each other in all of the excitation angle change resonators.

18. The acoustic wave device according to claim 1, wherein
at least one of the plurality of acoustic wave resonators is not the excitation angle change resonator; and
a shape of the plurality of electrode fingers of the at least one acoustic wave resonator that is not the excitation angle change resonator is linear in a plan view.

19. The acoustic wave device according to claim 18, wherein
in the at least one acoustic wave resonator that is not the excitation angle change resonator, the piezoelectric body layer includes a propagation axis;
the plurality of electrode fingers in the IDT electrode of the at least one acoustic wave resonator include a plurality of third electrode fingers and a plurality of fourth electrode fingers which are interdigitated with each other; and
when a virtual line connecting tips in tip portions of the plurality of fourth electrode fingers is defined as a third envelope curve, and a virtual line connecting tips in tip portions of the plurality of third electrode fingers is defined as a fourth envelope curve, the third envelope curve and the fourth envelope curve are inclined with respect to the propagation axis.

20. The acoustic wave device according to claim 1, wherein at least one of an electrode finger pitch and a duty ratio is constant in a portion where the excitation angles are the same or substantially the same in the IDT electrode of the excitation angle change resonator.

21. The acoustic wave device according to claim 1, wherein
the plurality of electrode fingers in the IDT electrode of the excitation angle change resonator include a plurality of first electrode fingers and a plurality of second electrode fingers which are interdigitated with each other;
a virtual line connecting tips in tip portions of the plurality of second electrode fingers is defined as a first envelope curve;
a virtual line connecting tips in tip portions of the plurality of first electrode fingers is defined as a second envelope curve;
a region between the first envelope curve and the second envelope curve is an intersection region in the IDT electrode; and
in the intersection region of the excitation angle change resonator, resonant frequencies or anti-resonant frequencies coincide or substantially coincide with each other.

22. The acoustic wave device according to claim 21, wherein
at least two of the plurality of acoustic wave resonators are the excitation angle change resonators;
in each of the intersection regions of the at least two of the excitation angle change resonators, the resonant frequencies coincide or substantially coincide with each other; and
when the resonant frequency of a portion where the excitation angle is about 0° in the intersection region is defined as a reference resonant frequency, a relationship in which a difference of the reference resonant frequency between the at least two excitation angle change resonators whose resonant frequencies coincides or substantially coincide with each other in the intersection region is equal to or smaller than about 2% with respect to the reference resonant frequency of any of the at least two excitation angle change resonators is provided in the at least two of the excitation angle change resonators.

23. The acoustic wave device according to claim 21, wherein
at least one of the plurality of acoustic wave resonators is not the excitation angle change resonator;
in the intersection region of the excitation angle change resonator, resonant frequencies coincide or substantially coincide with each other; and
when the resonant frequency of a portion where the excitation angle is about 0° in the intersection region is defined as a reference resonant frequency, a relationship in which a difference between the reference resonant frequency of the excitation angle change resonator whose resonant frequencies coincide or substantially coincide with each other in the intersection region and the resonance frequency of the at least one acoustic wave resonator that is not the excitation angle change resonator is equal to or smaller than about 2% with respect to any of the reference resonant frequency and the resonant frequency is established in the excitation angle change resonator and the at least one acoustic wave resonator that is not at least one of the excitation angle change resonators.

24. The acoustic wave device according to claim 21, wherein
at least two of the plurality of acoustic wave resonators are the excitation angle change resonators;
in each of the intersection regions of the at least two of the excitation angle change resonators, the resonant frequencies coincide or substantially coincide with each other; and
when the resonant frequency of a portion where the excitation angle is about 0° in the intersection region is defined as a reference resonant frequency, a relationship in which a difference of the reference resonant frequency between the at least two excitation angle change resonators whose resonant frequencies coincide or substantially coincide with each other in the intersection region is larger than about 2% with respect to the reference resonant frequency of any of the at least two excitation angle change resonators is established in the at least two of the excitation angle change resonators.

25. The acoustic wave device according to claim 21, wherein
at least one of the plurality of acoustic wave resonators is not the excitation angle change resonator;
in the intersection region of the excitation angle change resonator, the resonant frequencies coincide or substantially coincide with each other; and
when the resonant frequency of a portion where the excitation angle in the intersection region is about 0° is defined as a reference resonant frequency, a relationship in which a difference between the reference resonant frequency of the excitation angle change resonator whose resonant frequencies coincides or substantially coincide with each other in the intersection region and the resonant frequency of the at least one acoustic wave resonator that is not the excitation angle change resonator is larger than about 2% with respect to any of the reference resonant frequency and the resonant frequency is established in the excitation angle change resonator and the at least one acoustic wave resonator that is not at least one of the excitation angle change resonators.

26. The acoustic wave device according to claim 1, wherein
the plurality of electrode fingers in the IDT electrode of the excitation angle change resonator include a plurality of first electrode fingers and a plurality of second electrode fingers which interdigitate each other;
a virtual line connecting tips in tip portions of the plurality of second electrode fingers is defined as a first envelope curve;
a virtual line connecting tips in tip portions of the plurality of first electrode fingers is defined as a second envelope curve;
a region between the first envelope curve and the second envelope curve is an intersection region in the IDT electrode; and
the intersection region includes a first edge region including the first envelope curve, a second edge region including the second envelope curve, and a central region interposed between the first edge region and the second edge region; and
in the excitation angle change resonator, a low acoustic velocity region whose acoustic velocity is lower than an acoustic velocity in the central region is provided in at least a portion of at least one of the first edge region and the second edge region.

27. The acoustic wave device according to claim 26, wherein in at least one of the first edge region and the second edge region, at least one of the plurality of electrode fingers includes a wide portion whose width is greater than a width in the central region to define the low acoustic velocity region.

28. The acoustic wave device according to claim 26, further comprising:
a mass addition film overlapping at least one of the plurality of first electrode fingers and the plurality of second electrode fingers, when viewed in a plan view, in at least one of the first edge region and the second edge region; wherein
the low acoustic velocity region includes the mass addition film.

29. The acoustic wave device according to claim 26, wherein, in at least one of the first edge region and the second edge region, the low acoustic velocity region includes at least one of the plurality of electrode fingers with a thickness greater than a thickness of the at least one of the plurality of electrode fingers in the central region.

30. The acoustic wave device according to claim 26, wherein the low acoustic velocity region is provided in both of the first edge region and the second edge region.

31. The acoustic wave device according to claim 1, wherein
the piezoelectric substrate includes a support substrate; and
the piezoelectric body layer is provided on the support substrate.

32. The acoustic wave device according to claim 31, wherein the piezoelectric substrate includes an intermediate layer between the support substrate and the piezoelectric body layer.

33. The acoustic wave device according to claim 32, wherein
a hollow portion is provided in the piezoelectric substrate; and
a portion of the support substrate and a portion of the piezoelectric body layer face each other with the hollow portion interposed therebetween.

34. The acoustic wave device according to claim 1, wherein the piezoelectric substrate includes only the piezoelectric body layer.
